(19) United States
(12) Patent Application Publication
(10) Pub. No.: US 2026/0013231 A1
(43) Pub. Date: Jan. 8, 2026

(54) THIN FILM TRANSISTOR SUBSTRATE AND DISPLAY APPARATUS COMPRISING THE SAME

(71) Applicant: LG Display Co., Ltd., Seoul (KR)

(72) Inventors: Sungju CHOI, Paju-si (KR); Jaeyoon PARK, Paju-si (KR); Hyeonjoo SEUL, Paju-si (KR); Dongyeon KANG, Paju-si (KR)

(73) Assignee: LG Display Co., Ltd., Seoul (KR)

(21) Appl. No.: 19/194,994

(22) Filed: Apr. 30, 2025

(30) Foreign Application Priority Data
Jul. 8, 2024 (KR) 10-2024-0089750

(51) Int. Cl. H10D 86/40; H10D 86/60

(52) U.S. Cl. CPC H10D 86/481; H10D 86/431; H10D 86/60

(57) ABSTRACT

A thin film transistor substrate and a display apparatus including the same are discussed. The thin film transistor in some examples can include a base substrate, a first thin film transistor disposed on the base substrate, and a storage capacitor disposed on the base substrate. The first thin film transistor includes a first active layer disposed on the base substrate and having an oxide semiconductor material, a first gate electrode disposed on the first active layer, and a metal insulating layer overlapping the first active layer and the first gate electrode. The storage capacitor includes a first electrode disposed on the base substrate, a second electrode disposed on the first electrode, and the metal insulating layer disposed between the fist electrode and the second electrode. A resistivity of the metal insulating layer is higher than the resistivity of the active layer.

### CROSS-REFERENCE TO RELATED APPLICATIONS

This application claims priority to Korean Patent Application No. 10-2024-0089750, filed in the Republic of Korea on Jul. 8, 2024, the entire contents of which is hereby expressly incorporated by reference into the present application.

### BACKGROUND OF THE DISCLOSURE

### Field of the Technology

The present disclosure relates to a thin film transistor substrate and a display apparatus including the same.

### Discussion of the Related Art

Since thin film transistors can be manufactured on glass or plastic substrates, they are widely used as switching elements or driving elements in display apparatuses such as liquid crystal display apparatuses or organic light emitting devices.

Thin film transistors (TFTs) can be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, based on the material constituting the active layer.

Among these, oxide semiconductor thin film transistors (oxide semiconductor TFTs) have the advantage of high mobility and can have a large resistance change depending on the oxygen content, so they can easily obtain desired properties. In addition, since the oxide constituting the active layer can be formed at a relatively low temperature during the manufacturing process of oxide semiconductor thin film transistors, the manufacturing cost is low. Since oxide semiconductors are transparent due to the nature of oxides, they are also advantageous in implementing transparent display apparatuses.

In order to achieve improved gray scale expression of the driving thin film transistor, it is important to implement storage capacitance with improved electrostatic capacity for a small area. Furthermore, there is a concern that the characteristics of the thin film transistor can deteriorate if hydrogen generated during the process of forming multiple organic or inorganic films in the process of manufacturing the display apparatus reaches the active layer of the thin film transistor.

### SUMMARY OF THE DISCLOSURE

Various aspects of the present invention have been designed to solve and address limitations associated with the related art, and aim to provide a thin film transistor substrate including a storage capacitor having improved electrostatic capacity and a thin film transistor whose device characteristics are not degraded by hydrogen, and a display apparatus using the same.

Aspects of the present invention provide a thin film transistor including an active layer, a gate insulating layer on the active layer, a first gate electrode on the gate insulating layer, and a capping layer on the gate insulating layer. The gate electrode and the capping layer are spaced apart from each other, a part of the active layer overlaps the gate electrode, and another part of the active layer overlaps the capping layer.

Aspects of the present invention provide also provide a method for manufacturing such a thin film transistor and a display apparatus including the same.

The present invention will become more fully understood from the detailed description given hereinbelow and the accompanying drawings which are given by way of illustration only, and thus are not limitative of the present invention.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of a thin film transistor substrate according to one or more embodiments of the present invention.

FIG. 2 is a cross-sectional view of a first thin film transistor provided on a thin film transistor substrate according to one embodiment of the present invention. In this case, FIG. 2 relates to cross-section I-I′ of FIG. 1.

FIG. 3 is a cross-sectional view of a second thin film transistor and a storage capacitor provided on a thin film transistor substrate according to one embodiment of the present invention. In this case, FIG. 3 relates to cross-section II-II′ of FIG. 1.

FIG. 4 is a plan view of a first thin film transistor provided on a thin film transistor substrate according to another embodiment of the present invention.

FIG. 5 is a cross-sectional view of a first thin film transistor provided on a thin film transistor substrate according to another embodiment of the present invention. In this case, FIG. 5 is related to cross-section III-III′ of FIG. 4.

FIG. 6 is a cross-sectional view of a second thin film transistor and a storage capacitor provided on a thin film transistor substrate according to another embodiment of the present invention. In this case, FIG. 6 is related to cross-section IV-IV′ of FIG. 4.

FIG. 7 is a cross-sectional view of a second thin film transistor and a storage capacitor provided on a thin film transistor substrate according to another embodiment of the present invention. In this case, FIG. 7 is related to cross-section III-III′ of FIG. 4.

FIG. 8 is a cross-sectional view of a first thin film transistor provided on a thin film transistor substrate according to another embodiment of the present invention. In this case, FIG. 8 is related to cross-section IV-IV′ of FIG. 4.

FIG. 9 is a plan view of a thin film transistor substrate according to another embodiment of the present invention.

FIG. 10 is a cross-sectional view of a first thin film transistor provided on a thin film transistor substrate according to another embodiment of the present invention. In this case, FIG. 10 is a cross-sectional view V-V′ of FIG. 9.

FIG. 11 is a cross-sectional view of a second thin film transistor and a storage capacitor provided on a thin film transistor substrate according to another embodiment of the present invention. In this case, FIG. 11 is a cross-sectional view taken along line VI-VI′ of FIG. 9.

FIG. 12 is a plan view of a thin film transistor substrate according to another embodiment of the present invention.

FIG. 13 is a cross-sectional view of a first thin film transistor provided on a thin film transistor substrate according to another embodiment of the present invention. In this case, FIG. 13 is a cross-sectional view taken along line VII-VII′ of FIG. 12.

FIG. 14 is a cross-sectional view of a second thin film transistor and a storage capacitor provided on a thin film transistor substrate according to another embodiment of the present invention. In this case, FIG. 14 is a cross-sectional view taken along line VIII-VIII′ of FIG. 12.

FIG. 15 is a plan view of a thin film transistor substrate according to another embodiment of the present invention.

FIG. 16 is a cross-sectional view of a second thin film transistor and a storage capacitor provided on a thin film transistor substrate according to another embodiment of the present invention. In this case, FIG. 16 is a cross-sectional view taken along line IX-IX′ of FIG. 15.

FIGS. 17A to 17C are process cross-sectional views of a second thin film transistor and a storage capacitor provided on a thin film transistor substrate according to another embodiment of the present invention. In this case, FIGS. 17A to 17C are related to cross-section IX-IX′ of FIG. 15.

FIG. 18 is a plan view of a thin film transistor substrate according to another embodiment of the present invention.

FIG. 19 is a cross-sectional view of a first thin film transistor provided on a thin film transistor substrate according to another embodiment of the present invention. In this case, FIG. 19 is about cross-section X-X′ of FIG. 18.

FIG. 20 is a cross-sectional view of a second thin film transistor and a storage capacitor provided on a thin film transistor substrate according to another embodiment of the present invention. In this case, FIG. 20 is a cross-sectional view taken along line XI-XI′ of FIG. 18.

FIGS. 21A to 21G are process cross-sectional views of a second thin film transistor and a storage capacitor provided on a thin film transistor substrate according to another embodiment of the present invention. In this case, FIGS. 21A to 21G are cross-sectional views XI-XI′ of FIG. 18.

FIG. 22 is a cross-sectional view of a display apparatus according to one or more embodiments of the present invention.

FIG. 23 is a schematic plan view showing a display apparatus according to one or more embodiments of the present invention.

### DETAILED DESCRIPTION OF THE EMBODIMENTS

Advantages and features of the present disclosure and implementation methods thereof will be clarified through following embodiments described with reference to the accompanying drawings. The present disclosure may, however, be embodied in different forms and should not be construed as limited to the embodiments set forth herein. These embodiments are provided so that this disclosure will be thorough and complete and will be fully understood by those skilled in the art.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted or may be briefly provided. In a case where ‘comprise’, ‘have’ and ‘include’ described in the present disclosure are used, another portion can be added unless ‘only’ is used. The terms of a singular form can include plural forms unless referred to the contrary.

In construing an element, the element is construed as including an error band although there is no explicit description.

In describing a position relationship, for example, when the position relationship is described as ‘upon’, ‘above’, ‘below’ and ‘next to’, one or more portions can be disposed between two other portions unless ‘just’ or ‘direct’ is used.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship. Further, the term “can” encompasses all the meanings and coverages of the term “may” and vice versa.

Hereinafter, various embodiments of the present invention will be described in detail with reference to the drawings. All the components of each display device or apparatus according to all embodiments of the present invention are operatively coupled and configured.

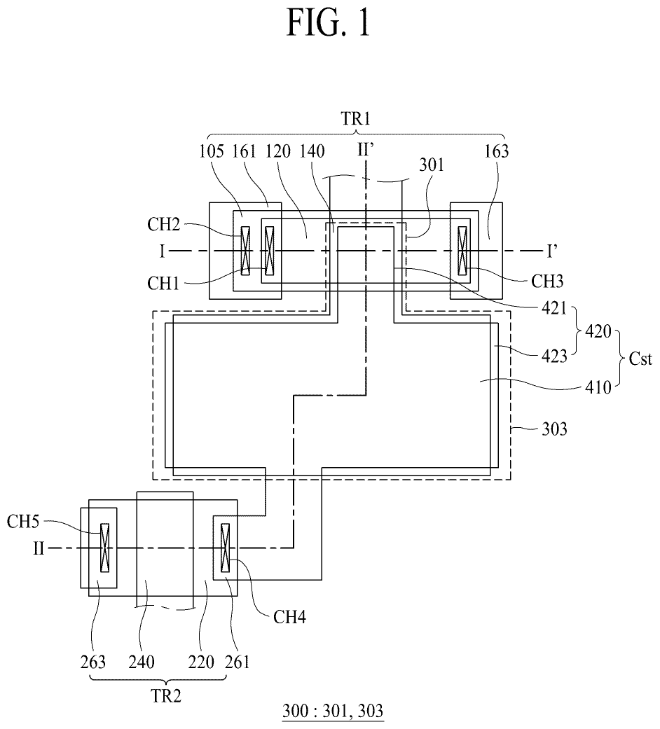

FIG. 1 is a plan view of a thin film transistor substrate according to one or more embodiments of the present invention.

As can be seen from FIG. 1, a thin film transistor substrate according to an embodiment of the present invention includes a first thin film transistor (TR1), a second thin film transistor (TR2), and a storage capacitor (Cst) provided between the first thin film transistor (TR1) and the second thin film transistor (TR2). In this case, the first thin film transistor (TR1) can be a driving thin film transistor, and the second thin film transistor (TR2) can be a light-emitting control transistor, but is not limited thereto.

The first thin film transistor (TR1) includes a light-shielding layer (105), a first active layer (120), a first gate electrode (140), a first source electrode (161), and a first drain electrode (163).

The light-shielding layer (105) can extend in a first direction, for example, a horizontal direction. The light-shielding layer (105) can be provided to overlap with the first active layer (120). Specifically, the light-shielding layer (105) can be provided to overlap with the entire first active layer (120). However, the present invention is not limited thereto.

The light-shielding layer (105) can be electrically connected to the first source electrode (161) through the second contact hole (CH2).

The first active layer (120) can extend in a first direction, for example, a horizontal direction.

The first gate electrode (140) can extend in a second direction, for example, a vertical direction, and can be provided to overlap the first active layer (120). In this case, the second direction can be a direction orthogonal to the first direction.

The first source electrode (161) and the first drain electrode (163) can be provided on one side and the other side of the first active layer (120), respectively. For example, the first source electrode (161) can be provided on the left side of the first active layer (120) and can be electrically connected to the first active layer (120) through a first contact hole (CH1), and the first drain electrode (163) can be provided on the right side of the first active layer (120) and can be electrically connected to the first active layer (120) through a third contact hole (CH3).

The second thin film transistor (TR2) includes a second active layer (220), a second gate electrode (240), a second source electrode (261), and a second drain electrode (263).

The second active layer (220) can extend in a first direction, for example, a horizontal direction.

The second gate electrode (240) can extend in a second direction, for example, a vertical direction, and can be provided to overlap a portion of the second active layer (220).

The second source electrode (261) and the second drain electrode (263) can be provided on one side and the other side of the second active layer (220), respectively. For example, the second source electrode (261) can be provided on the right side of the second active layer (220) and can be electrically connected to the second active layer (220) through a fourth contact hole (CH4), and the second drain electrode (263) can be provided on the left side of the second active layer (220) and can be electrically connected to the second active layer (220) through a fifth contact hole (CH5).

The storage capacitor (Cst) includes a first electrode (410), a second electrode (420), and a metal insulating layer (300) provided between the first electrode (410) and the second electrode (420).

The first electrode (410) and the second electrode (420) can be spaced apart from each with the metal insulating layer (300) interposed therebetween so as to overlap with each other. The first electrode (410) and the second electrode (420) can be spaced apart from each other so as to overlap each other in some areas, so that capacitance can be formed by different electric fields applied to each of the first electrode (410) and the second electrode (420).

The first electrode (410) can be a portion from which the first gate electrode (140) of the first thin film transistor (TR1) extends. In other words, the first electrode (410) of the storage capacitor (Cst) can be configured by extending the first gate electrode (140) of the first thin film transistor (TR1). Alternatively, the first electrode (410) of the storage capacitor (Cst) can be formed integrally with the first gate electrode (140) of the first thin film transistor (TR1).

According to one embodiment of the present invention, the first electrode (410) can be formed integrally with the first gate electrode (140) of the first thin film transistor (TR1), and by being formed in this manner, the first electrode (410) of the storage capacitor (Cst) and the first gate electrode (140) of the first thin film transistor (TR1) can be formed using the same material in the same process.

The second electrode (420) can be a portion from which the second source electrode (261) of the second thin film transistor (TR2) extends. In other words, the second electrode (420) of the storage capacitor (Cst) can be configured by extending the second source electrode (261) of the second thin film transistor (TR2). Alternatively, the second electrode (420) of the storage capacitor (Cst) can be formed integrally with the second source electrode (261) of the second thin film transistor (TR2). However, the present invention is not limited thereto.

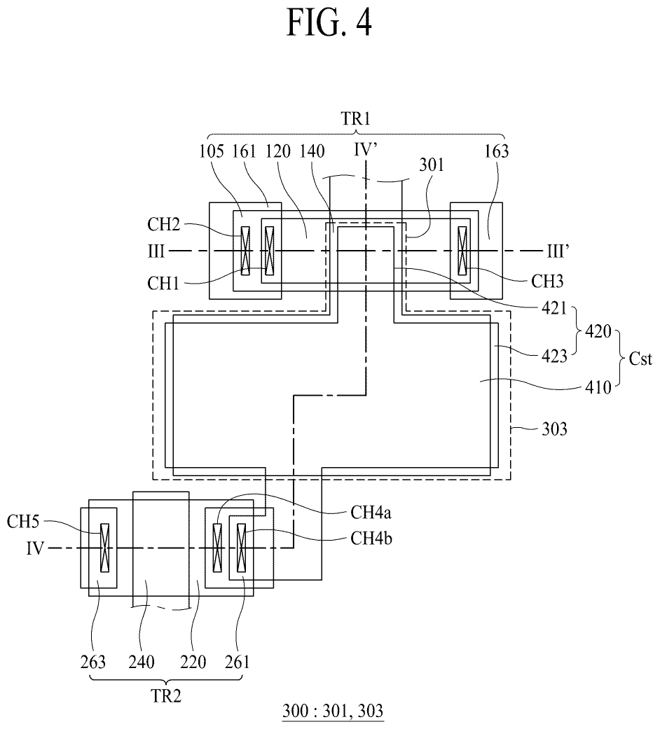

Meanwhile, in FIG. 1, the second electrode (420) is shown as being formed integrally with the second source electrode (261), but it is not limited thereto, and as in the embodiment of FIG. 4, the second electrode (420) can be electrically connected to the second source electrode (261) formed as a connecting electrode or bridge electrode through a separate contact hole. This will be described in more detail later with reference to FIG. 4.

The second electrode (420) includes a first part (421) and a second part (423). The first part (421) and the second part (423) can be provided as one piece.

The first portion (421) can overlap with the first thin film transistor (TR1). The first portion (421) can overlap with the first active layer (120) and/or the first gate electrode (140) of the first thin film transistor (TR1). According to one embodiment of the present invention, the first gate electrode (140) and the first portion (421) are spaced apart from each other so as to overlap each other with the metal insulating layer (300) interposed therebetween, so that a storage capacitor can be formed in a portion of the first thin film transistor (TR1). In this case, by controlling or omitting the area of the first portion (421), the electrostatic capacitance for driving the first thin film transistor (TR1) can be appropriately controlled.

The second portion (423) can be electrically connected to the second thin film transistor (TR2). Specifically, the second portion (423) can be extended and formed integrally with the second source electrode (261) of the second thin film transistor (TR2). In other words, the second electrode (410) of the storage capacitor (Cst) can be configured as the second source electrode (261) of the second thin film transistor (TR2).

The metal insulating layer (300) can be provided continuously in an area where the first thin film transistor (TR1) and the storage capacitor (Cst) are formed. Specifically, the metal insulating layer (300) includes a first metal insulating layer (301) and a second metal insulating layer (303), and the first metal insulating layer (301) and the second metal insulating layer (303) can be provided continuously with each other.

The first metal insulating layer (301) can overlap a portion of the first thin film transistor (TR1). Specifically, the first metal insulating layer (301) can overlap the first active layer (120) and the first gate electrode (140).

The second metal insulating layer (303) can be provided to overlap the first electrode (410) and the second electrode (420). The second metal insulating layer (303) can be provided between the first electrode (410) and the second electrode (420), so that when different electric fields are applied to the first electrode (410) and the second electrode (420), capacitance can be formed in the storage capacitor (Cst).

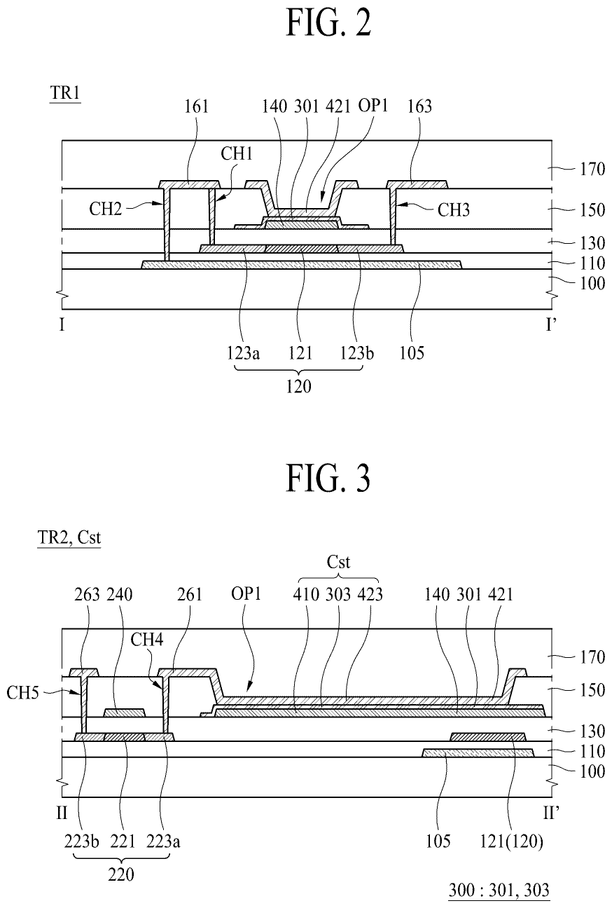

FIG. 2 is a cross-sectional view of a first thin film transistor provided on a thin film transistor substrate according to one embodiment of the present invention. In this case, FIG. 2 relates to cross-section I-I′ of FIG. 1.

As can be seen in FIG. 2, a thin film transistor according to one embodiment of the present invention includes a substrate (100), a light-shielding layer (105), a buffer layer (110), a first active layer (120), a gate insulating layer (130), a first gate electrode (140), a first metal insulating layer (301), an interlayer insulating layer (150), a first source electrode (161), a first drain electrode (162), a first portion (421), and a planarizing layer (170).

The substrate (100) can be made of glass or plastic. In particular, the substrate (100) can be made of a transparent plastic having flexible properties, for example, polyimide. When polyimide is used as the substrate (100), considering that a high-temperature deposition process is performed on the substrate (100), a heat-resistant polyimide that can withstand high temperatures can be used.

The light-shielding layer (105) can be provided on the substrate (100). The light-shielding layer (105) can be formed of a metal or a metal oxide, and can be formed of one metal layer or metal oxide layer, or can be formed of two or more metal layers or metal oxide layers.

The light-shielding layer (105) is provided under the first active layer (120) and overlaps with the first active layer (120), thereby preventing light from the outside of the thin film transistor substrate from entering the first active layer (120). Specifically, the light-shielding layer (105) can prevent external light from entering the first channel portion (121) of the first active layer (120). Meanwhile, a separate insulating layer can be additionally provided between the light-shielding layer (105) and the substrate (100).

The buffer layer (110) is formed on the substrate (100) and the light-shielding layer (105). The buffer layer (110) can protect the first active layer (120) by blocking air and moisture. The buffer layer (110) can be formed of an inorganic insulating material such as silicon oxide, silicon nitride, or metal oxide, but is not necessarily limited thereto and can be formed of an organic insulating material. The buffer layer (110) can be formed of a single layer or can be formed of a plurality of layers.

The first active layer (120) can be disposed on the buffer layer (110).

The first active layer (120) can be formed of a semiconductor material, for example, an oxide semiconductor material. The oxide semiconductor material can include, for example, at least one of IZO (InZnO)-based oxide semiconductor material, IGO (InGaO)-based oxide semiconductor material, ITO (InSnO)-based oxide semiconductor material, IGZO (InGaZnO)-based oxide semiconductor material, IGZTO (InGaZnSnO)-based oxide semiconductor material, GZTO (GaZnSnO)-based oxide semiconductor material, GZO (GaZnO)-based oxide semiconductor material, ITZO (InSnZnO)-based oxide semiconductor material, and FIZO (FeInZnO)-based oxide semiconductor material.

The first active layer (120) includes a first channel portion (121), a first connection portion (123a) connected to one side of the first channel portion (121), and a second connection portion (123b) connected to the other side of the first channel portion (121). The first connection portion (123a) and the second connection portion (123b) can be provided with conductive properties by a conductive process that performs ion doping or plasma treatment on a semiconductor material using the first gate electrode (140) as a mask.

The conductive process can be defined as a process of imparting conductive properties to an oxide semiconductor material. An oxide semiconductor material that has undergone the conductive process can have conductive properties. The conductive process can include, for example, a doping process using dopant ions and a plasma process of applying plasma to make it conductive. Through the conductive process, a portion of the first active layer (120) can be conductive and have conductive properties. In this case, the first connection portion (123a) and the second connection portion (123b) can be conductive and have conductive properties by the conductive process, and the first connection portion (123a) and the second connection portion (123b) have superior conductivity compared to the first channel portion (121), and each can also function as a wiring or a source/drain electrode.

The gate insulating layer (130) can be disposed on the first active layer (120). Specifically, the gate insulating layer (130) can be provided on the entire surface of the substrate (100) and can be disposed on the first active layer (120) and the buffer layer (110). As a result, the first active layer (120) can be provided in a form in which it is wrapped by the buffer layer (110) and the gate insulating layer (130).

The gate insulating layer (130) can include, but is not limited to, a silicon nitride film (SiNx) or a silicon oxide film (SiOx). The gate insulating layer (130) can be formed of a single layer or multiple layers including an inorganic insulating material and/or an organic insulating material.

The first gate electrode (140) can be disposed on the gate insulating layer (130). The first gate electrode (140) can be disposed on the first active layer (120). Specifically, the first gate electrode (140) can overlap the first channel portion (121) of the first active layer (120).

The first gate electrode (140) can include at least one of an aluminum-based metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The first gate electrode (140) can have a structure including one metal layer or a multilayer film structure including at least two metal layers each having different physical properties.

The first metal insulating layer (301) can be provided to overlap the first active layer (120) and the first gate electrode (140), and according to one embodiment of the present invention, the first metal insulating layer (301) can be provided between the first active layer (120) and the first gate electrode (140). The first metal insulating layer (301) can be provided on the first gate electrode (140). The first metal insulating layer (301) can be provided to cover the first gate electrode (140). Specifically, the first metal insulating layer (301) can be provided to cover the upper surface, one side surface, for example, the left side surface, and the other side surface, for example, the right side surface, of the first gate electrode (140).

The first metal insulating layer (301) is provided to cover the first gate electrode (140), so that it can be provided to overlap with the first channel portion (121) of the first active layer (120).

The first metal insulating layer (301) can be formed of a material that is easy to capture hydrogen. For example, the first metal insulating layer (301) can be formed of a semiconductor material or a metal oxide material. For example, the first metal insulating layer (301) can be formed of an oxide semiconductor material. The oxide semiconductor material can include at least one of, for example, IGO (InGaO)-based oxide semiconductor material, IGZO (InGaZnO)-based oxide semiconductor material, IGZTO (InGaZnSnO)-based oxide semiconductor material, GZTO (GaZnSnO)-based oxide semiconductor material, GZO (GaZnO)-based oxide semiconductor material, GO (GaO)-based oxide semiconductor material, and ZO (ZnO)-based oxide semiconductor material. As another example, the first metal insulating layer (301) can be formed of a metal oxide material. The metal oxide material can include, for example, at least one of titanium oxide (TiO), aluminum oxide (AlO), and molybdenum oxide (MoO).

The first metal insulating layer (301) can be provided to have a higher resistivity than the first active layer (120). For example, the first metal insulating layer (301) can have a resistivity of 1.0×10⁶ Ω·cm or more. However, it is not limited thereto.

The first metal insulating layer (301) can be provided to have a lower carrier concentration than the first active layer (120). For example, the first metal insulating layer (301) can have a carrier concentration of 1×10¹⁶ EA/cm³ or less. However, it is not limited thereto.

The first metal insulating layer (301) can be provided to have a higher oxygen concentration than the first active layer (120).

According to one embodiment of the present invention, the first metal insulating layer (301) is provided to cover the first gate electrode (140) and overlap with the first channel portion (121) of the first active layer (120), thereby preventing hydrogen generated during the process of manufacturing the thin film transistor substrate and the display apparatus according to one embodiment of the present invention from flowing into the first active layer (120). For example, when a heat treatment process is performed during the process of forming a planarization layer or an encapsulation layer provided on the first metal insulating layer (301), a large amount of hydrogen can flow into the first channel portion (121) of the first active layer (120) from the upper surface of the thin film transistor substrate and/or the display apparatus. If hydrogen flows into the first channel portion (121), the first channel portion (121) can partially become conductive, thereby deteriorating the device characteristics of the first thin film transistor (TR1). In this case, the metal insulating layer (130) is provided to cover the first gate electrode (140) and overlap with the first channel portion (121) of the first active layer (120), so that hydrogen generated through the heat treatment process can be captured by the first metal insulating layer (301) before reaching the first channel portion (121), thereby preventing the semiconductor characteristics of the first channel portion (121) from being deteriorated.

According to one embodiment of the present invention, the dielectric constant of the first metal insulating layer (301) can be 10 or more and 15 or less.

According to one embodiment of the present invention, the first metal insulating layer (301) can have a thickness thinner than the first active layer (120). By being formed in this manner, the first metal insulating layer (301) can function as an insulating layer without having conductive characteristics even when an electric field is applied to the first gate electrode (140) and/or the first portion (421). For example, the thickness of the first metal insulating layer (301) can be 1.2 Å or more and less than 30 Å. When the thickness of the first metal insulating layer (301) is less than 1.2 Å, the thickness of the first metal insulating layer (301) can be too thin and can have an uneven film quality, and when the thickness of the first metal insulating layer (301) exceeds 30 Å, when an electric field is applied to the first gate electrode (140) and/or the first portion (421) provided and below the first metal insulating layer (301), conductive properties can be obtained, and a short circuit can occur between the first gate electrode (140) and the first portion (421).

The first metal insulating layer (301) can be formed, for example, through sputtering or atomic layer deposition (ALD), but is not limited thereto.

The interlayer insulating layer (150) can be disposed on the first gate electrode (140) and the first metal insulating layer (301).

The interlayer insulating layer (150) insulates between the first gate electrode (140) and the first source electrode (161), and further insulates between the first gate electrode (140) and the first drain electrode (163). The interlayer insulating layer (150) can be formed of a single layer or multiple layers including an inorganic insulating material and/or an organic insulating material.

The interlayer insulating layer (150) includes a first contact hole (CH1), a second contact hole (CH2), and a third contact hole (CH3). Accordingly, a part of the upper surface of the first connection portion (123a) of the first active layer (120) can be exposed by the first contact hole (CH1). In addition, a part of the upper surface of the light-shielding layer (105) can be exposed by the second contact hole (CH2). Furthermore, a part of the upper surface of the second connection portion (123b) of the first active layer (120) can be exposed by the third contact hole (CH3).

According to one embodiment of the present invention, the interlayer insulating layer (150) can have a first open portion (OP1). In this case, a portion of the upper surface of the first metal insulating layer (301) provided under the interlayer insulating layer (150) can be exposed by the first open portion (OP1).

The first source electrode (161) can be electrically connected to one side of the first active layer (120), for example, the first connection portion (123a), and the first drain electrode (163) can be electrically connected to the other side of the first active layer (120), for example, the second connection portion (123b). In detail, the first source electrode (161) can be connected to the first connection portion (123a) of the first active layer (120) through the first contact hole (CH1) provided in the gate insulating layer (130) and the interlayer insulating layer (150), and can be electrically connected to the light-shielding layer (105) through the second contact hole (CH2). By electrically connecting the first source electrode (161) and the light shielding layer (105) through the second contact hole (CH2), the electrostatic capacitance of the storage capacitor (see Cst in FIG. 1) can be improved.

The first drain electrode (163) can be connected to the second connection portion (123b) of the first active layer (120) through the third contact hole (CH3) provided in the gate insulating layer (130) and the interlayer insulating layer (150).

The first part (421) can be disposed on the interlayer insulating layer (150).

The first portion (421) can overlap with the first open portion (OP1) of the interlayer insulating layer (150). More specifically, the first portion (421) can be formed in the first open portion (OP1) so as to be in contact with the upper surface of the interlayer insulating layer (150), the side surface of the interlayer insulating layer (150), and a portion of the upper surface of the first metal insulating layer (301) exposed by the first open portion (OP1).

Furthermore, by the first open portion (OP1), the first portion (421) can be formed using the same material in the same process as the first source electrode (161) and the first drain electrode (163). However, it is not limited thereto, and the first portion (421) can also be formed in a different layer from the first source electrode (161) and the first drain electrode (163).

The first source electrode (161) and the first drain electrode (163) can be disposed on the interlayer insulating layer (150). The first source electrode (161) and the first drain electrode (163) can be formed of the same material as the first gate electrode (140), but are not limited thereto and can be formed of a material according to knowledge in the art.

According to one embodiment of the present invention, the first gate electrode (140), the first metal insulating layer (301), and the first portion (421) are sequentially formed, so that a high electrostatic capacitance can be charged between the first gate electrode (140) and the first portion (421). As described above, the first metal insulating layer (301) can comprise a high dielectric constant material having a relatively high permittivity, such that a high capacitance can be formed between the first gate electrode (140) and the first portion (421).

Meanwhile, in FIG. 2, only the first part (421) formed on the first gate electrode (140) and the first metal insulating layer (301) is illustrated, but this is not limited thereto, and the first part (421) can be omitted depending on the case. In this way, when the first part (421) is formed, the first metal insulating layer (301) and the first part (421) are provided in the area overlapping the first gate electrode (140), thereby forming a high electrostatic capacitance, and when the first part (421) is not formed, it is possible to control so that a separate electrostatic capacitance is not formed in the area overlapping the first gate electrode (140).

The flattening layer (170) can be disposed on the interlayer insulating layer (150).

The planarization layer (170) can be disposed on the interlayer insulating layer (150), the first source electrode (161), the first drain electrode (163), and the first portion (421) so that the upper surface of the planarization layer (170) is planarized.

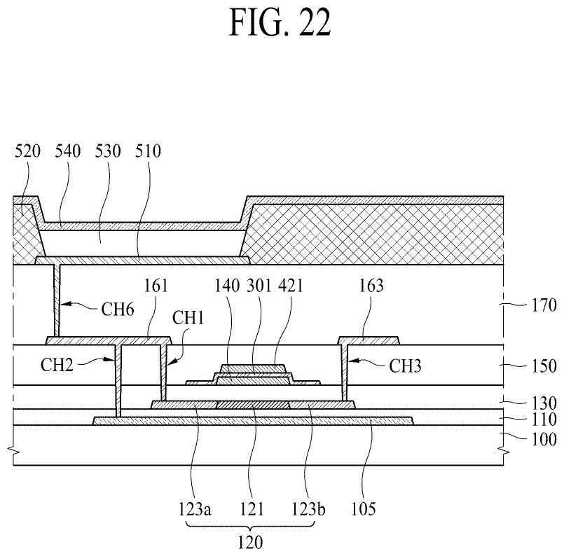

Meanwhile, a contact hole can be provided in the flattening layer (170) to expose a portion of the upper surface of the first source electrode (161) of the first thin film transistor (TR1). This will be described in more detail in the embodiment of FIG. 22.

The flattening layer (170) can be composed of an organic insulating material. The flattening layer (170) can be composed of an organic insulating material, such as, for example, an acrylic resin, an epoxy resin, a phenolic resin, a polyamide resin, or a polyimide resin.

FIG. 3 is a cross-sectional view of a second thin film transistor and a storage capacitor provided on a thin film transistor substrate according to one embodiment of the present invention. In this case, FIG. 3 relates to cross-section II-II′ of FIG. 1. Meanwhile, the embodiment of FIG. 3 relates to the same embodiment as the embodiment of FIG. 2, and the same components are given the same drawing reference numerals, and descriptions of repeated components are omitted or may be briefly provided.

As can be seen in FIG. 3, a thin film transistor substrate according to one embodiment of the present invention comprises a second thin film transistor (TR2) and a storage capacitor (Cst).

The second thin film transistor (TR2) includes a second active layer (220), a second gate electrode (240), a second source electrode (261), and a second drain electrode (263).

The second active layer (220) is disposed on the buffer layer (110). The second active layer (220) can be formed in the same layer as the first active layer (120). In this case, the first active layer (120) and the second active layer (220) can be formed in the same layer through the same process, thereby reducing the manufacturing cost. Meanwhile, the present invention is not limited thereto, and the second active layer (220) can be formed in a different layer from the first active layer (120).

The second active layer (220) can be formed of a semiconductor material, for example, an oxide semiconductor material. The oxide semiconductor material can include, for example, at least one of IZO (InZnO)-based oxide semiconductor material, IGO (InGaO)-based oxide semiconductor material, ITO (InSnO)-based oxide semiconductor material, IGZO (InGaZnO)-based oxide semiconductor material, IGZTO (InGaZnSnO)-based oxide semiconductor material, GZTO (GaZnSnO)-based oxide semiconductor material, GZO (GaZnO)-based oxide semiconductor material, ITZO (InSnZnO)-based oxide semiconductor material, and FIZO (FeInZnO)-based oxide semiconductor material.

The second active layer (220) comprises a second channel portion (221), a third connection portion (223a) connected to one side of the second channel portion (221), and a fourth connection portion (223b) connected to the other side of the second channel portion (221). The third connection portion (223a) and the fourth connection portion (223b) can be provided with conductive properties by a conductive process that performs ion doping or plasma treatment on a semiconductor material using the second gate electrode (240) as a mask.

Through the above-described conductive process, a portion of the second active layer (220) can be conductive and have conductive properties. In this case, the third connecting portion (223a) and the fourth connecting portion (223b) can be conductive and have conductive properties through the above-described conductive process, and the third connecting portion (223a) and the fourth connecting portion (223b) have superior conductivity compared to the second channel portion (221), and each can also function as a wiring or a source/drain electrode.

The second gate electrode (240) can be disposed on the gate insulating layer (130). The second gate electrode (240) can be disposed on the second active layer (220). Specifically, the second gate electrode (240) can overlap the second channel portion (221) of the second active layer (220).

The second gate electrode (240) can include at least one of an aluminum-based metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The second gate electrode (240) can have a structure including one metal layer or a multilayer film structure including at least two metal layers each having different physical properties.

The second source electrode (261) and the second drain electrode (263) can be disposed on the interlayer insulating layer (150). The second source electrode (261) and the second drain electrode (263) can be formed of the same material as the second gate electrode (240), but are not limited thereto and can be formed of a material according to knowledge in the art.

The second source electrode (261) can be electrically connected to one side of the second active layer (220), for example, the third connection portion (223a), and the second drain electrode (263) can be electrically connected to the other side of the second active layer (220), for example, the fourth connection portion (223b). In detail, the second source electrode (261) can be connected to the third connection portion (223a) of the second active layer (220) through the fourth contact hole (CH4) provided in the gate insulating layer (130) and the interlayer insulating layer (150), and the second drain electrode (263) can be connected to the fourth connection portion (223b) of the second active layer (220) through the fourth contact hole (CH4) provided in the gate insulating layer (130) and the interlayer insulating layer (150).

The storage capacitor (Cst) includes the first electrode (410), the second metal insulating layer (303), and the second portion (423) of the second electrode (420). According to one embodiment of the present invention, the second metal insulating layer (303) includes a high-k dielectric material having a relatively high dielectric constant, so that the electrostatic capacitance formed between the first electrode (410) and the second electrode (420) can be improved. Accordingly, when the first thin film transistor (TR1) expresses gray scale, it can have an improved contrast ratio.

The first electrode (410) can be formed by extending a portion of the first gate electrode (140) of the first thin film transistor (TR1). Accordingly, the first electrode (410) can be formed using the same material as the first gate electrode (140) in the same process.

The second metal insulating layer (303) can be formed on the first electrode (410).

According to one embodiment of the present invention, the second metal insulating layer (303) can be formed to include the same material in the same layer as the first metal insulating layer (301). Therefore, the second metal insulating layer (303) can be provided continuously with the first metal insulating layer (301). Therefore, by forming the first metal insulating layer (301) of the first thin film transistor (TR1) and the second metal insulating layer (302) of the storage capacitor (Cst) in the same layer in the same process, the number of manufacturing processes and the manufacturing time can be reduced.

The second metal insulating layer (303) can be formed of a material that is easy to capture hydrogen. For example, the second metal insulating layer (303) can be formed of a semiconductor material or a metal oxide material. For example, the second metal insulating layer (303) can be formed of oxide semiconductor material. The oxide semiconductor material can include at least one of, for example, an IGO (InGaO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, a GO (GaO)-based oxide semiconductor material, and a ZO (ZnO)-based oxide semiconductor material. As another example, the second metal insulating layer (303) can be formed of a metal oxide material. The metal oxide material can include, for example, at least one of titanium oxide (TiO), aluminum oxide (AlO), and molybdenum oxide (MoO).

The second metal insulating layer (303) can be provided to cover one side of the first electrode (410), for example, the left side. However, it is not limited thereto.

The second part (423) of the second electrode (420) can be disposed on the second metal insulating layer (303). In detail, the second part (423) can be in contact with the upper surface of the interlayer insulating layer (150), the side surface of the interlayer insulating layer (150), and a portion of the upper surface of the second metal insulating layer (303) by the first open portion (OP1).

The second part (423) can be formed continuously with the first part (421).

FIG. 4 is a plan view of a first thin film transistor provided on a thin film transistor substrate according to another embodiment of the present invention. Meanwhile, the embodiment of FIG. 4 is identical to the embodiment of FIG. 1 except that the second source electrode is provided in the form of a connection electrode, so the following description will focus on the different configuration.

As can be seen in FIG. 4, a thin film transistor substrate according to another embodiment of the present invention comprises a first thin film transistor (TR1), a second thin film transistor (TR2), and a storage capacitor (Cst) provided between the first thin film transistor (TR1) and the second thin film transistor (TR2).

According to the embodiment of FIG. 4, unlike the embodiment of FIG. 1, the second thin film transistor (TR2) and the storage capacitor (Cst) can be electrically connected by the second source electrode (261) provided in the form of a connecting electrode or a bridge electrode. In detail, the second source electrode (261) can be electrically connected to one side, for example, the right side, of the second active layer (220) through the 4-1 contact hole (CH4a), and the second source electrode (261) can be electrically connected to the first electrode (410) of the storage capacitor (Cst) through the 4-2 contact hole (CH4b).

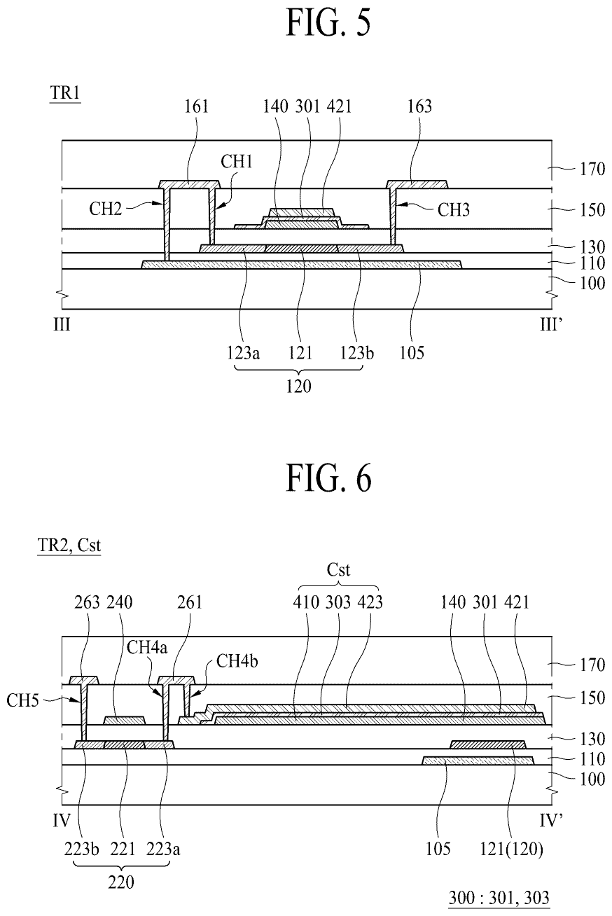

FIG. 5 is a cross-sectional view of a first thin film transistor provided on a thin film transistor substrate according to another embodiment of the present invention. In this case, FIG. 5 is related to cross-section III-III′ of FIG. 4. Meanwhile, the embodiment of FIG. 5 is the same as the embodiment of FIG. 2 except for the configuration of the interlayer insulating layer and the first portion, so the following description will focus on the different configuration.

As can be seen in FIG. 5, the first thin film transistor (TR1) according to another embodiment of the present invention may not form a separate open portion in the interlayer insulating layer (150), unlike the embodiment of FIG. 2. Accordingly, the first portion (421) can be disposed on the first metal insulating layer (301), and the interlayer insulating layer (150) can be disposed on the first portion (421). In this case, the interlayer insulating layer (150) can be provided to cover the first portion (421).

Since the first part (421) is provided under the interlayer insulating layer (150), it is provided in a different layer from the first source electrode (161) and the first drain electrode (163), and the first part (421) can be formed through a different process from the first source electrode (161) and the first drain electrode (163).

FIG. 6 is a cross-sectional view of a second thin film transistor and a storage capacitor provided on a thin film transistor substrate according to another embodiment of the present invention. In this case, FIG. 6 is related to cross-section IV-IV′ of FIG. 4. Meanwhile, the embodiment of FIG. 6 is the same as the embodiment of FIG. 3 except for the configuration of the interlayer insulating layer, the second portion, and the second source electrode, so the following description will focus on the different configurations.

As can be seen in FIG. 6, the second thin film transistor (TR2) can be electrically connected to the storage capacitor (Cst) through the second source electrode (261) formed as a connecting electrode or a bridge electrode. In detail, the second source electrode (261) of the second thin film transistor (TR2) according to another embodiment of the present invention can be electrically connected to one side, for example, the right side, of the second active layer (220) through the 4-1 contact hole (CH4a). The second source electrode (261) can be electrically connected to the second electrode (420) of the storage capacitor (Cst) through the 4-2 contact hole (CH4b). In this way, by means of the second source electrode (261) provided in the form of a connecting electrode or a bridge electrode, the second part (423) of the second electrode (420) of the storage capacitor (Cst) can be formed on the second metal insulating layer (303) without forming a separate open portion in the interlayer insulating layer (150).

The second portion (423) can be formed under the interlayer insulating layer (150) and can be provided to be covered by the interlayer insulating layer (150).

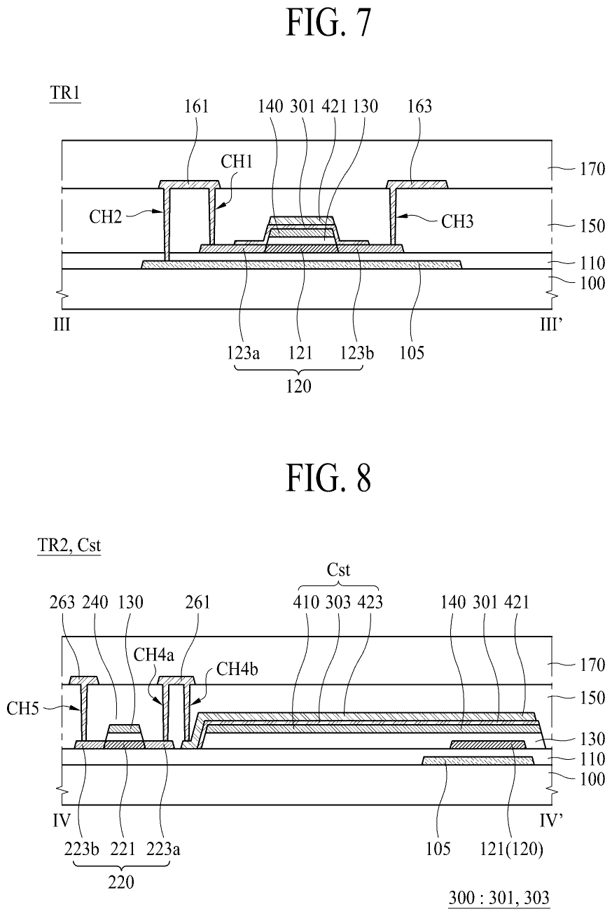

FIG. 7 is a cross-sectional view of a second thin film transistor and a storage capacitor provided on a thin film transistor substrate according to another embodiment of the present invention. In this case, FIG. 7 is related to cross-section III-III′ of FIG. 4. Meanwhile, the embodiment of FIG. 7 is the same as the embodiment of FIG. 5 except for the configuration of the gate insulating layer, so the following description will focus on the different configuration.

As can be seen in FIG. 7, a first thin film transistor (TR1) according to another embodiment of the present invention is provided between the first active layer (120) and the first gate electrode (140), and includes an etched gate insulating layer (130).

According to another embodiment of the present invention, the gate insulating layer (130) can be etched using the first gate electrode (140) as a mask to correspond to one end and the other end of the first gate electrode (140). In detail, one end and the other end of the gate insulating layer (130), for example, the left end and the right end, can be formed in an island shape corresponding to one end and the other end of the first gate electrode (140), for example, the left end and the right end, respectively. In this disclosure, the form in which the gate insulating layer (130) is formed in an island shape can be defined as an etch structure.

In the case where the gate insulating layer (130) is formed with the etch structure, the first metal insulating layer (301) provided on the first gate electrode (140) can be provided to cover a portion of the upper surface of the first active layer (120). In detail, the first metal insulating layer (301) can cover a portion of the upper surface of the first connecting portion (123a) and the second connecting portion (123b) of the first active layer (120).

In addition, the first metal insulating layer (301) can be provided to cover one side surface and the other side surface of the gate insulating layer (130). In detail, the first metal insulating layer (301) can cover the left side surface and the right side surface of the gate insulating layer (130).

FIG. 8 is a cross-sectional view of a first thin film transistor provided on a thin film transistor substrate according to another embodiment of the present invention. In this case, FIG. 8 is related to cross-section IV-IV′ of FIG. 4. Meanwhile, the embodiment of FIG. 8 is the same as the embodiment of FIG. 6 except for the configuration of the gate insulating layer, so the following description will focus on the different configuration.

As can be seen in FIG. 8, a second thin film transistor (TR2) according to another embodiment of the present invention is provided between the second active layer (220) and the second gate electrode (240) and includes a gate insulating layer (130) formed by etching. For example, the second thin film transistor (TR2) can be formed by including the gate insulating layer (130) formed by etching.

The storage capacitor (Cst) is formed by including the first electrode (410), the second metal insulating layer (303), and the second part (423) of the second electrode (420) provided on the gate insulating layer (130) formed in an island shape. In this case, since the gate insulating layer (130) is formed by etching using the first electrode (410) as a mask, one end and the other end of the gate insulating layer (130) can correspond to one end and the other end of the first electrode (410), respectively.

In this case, the second metal insulating layer (303) can be provided to cover one side surface of the island-shaped gate insulating layer (130), for example, the right side surface, but is not limited thereto.

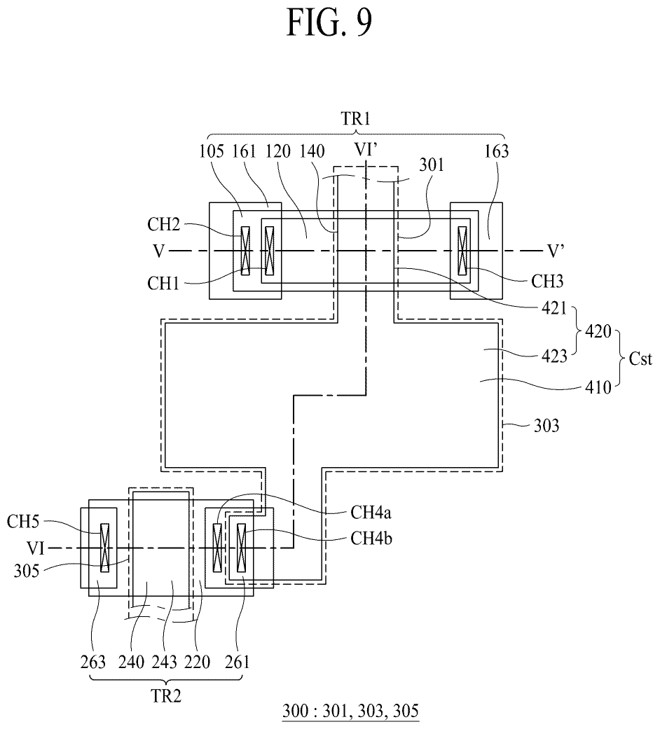

FIG. 9 is a plan view of a thin film transistor substrate according to another embodiment of the present invention. Meanwhile, the embodiment of FIG. 9 is identical to the embodiment of FIG. 4 except for the configuration of the first gate electrode, the second gate electrode, the metal insulating layer, and the storage capacitor, so the following description will focus on the different configuration.

As can be seen in FIG. 9, a thin film transistor substrate according to another embodiment of the present invention includes a first thin film transistor (TR1), a second thin film transistor (TR2), and a storage capacitor (Cst). Unlike the embodiment of FIG. 4, the thin film transistor substrate according to FIG. 9 can have the first gate electrode (140), the second gate electrode (240), the metal insulating layer (300), the first electrode (420), and the second electrode (420) pattern-formed simultaneously.

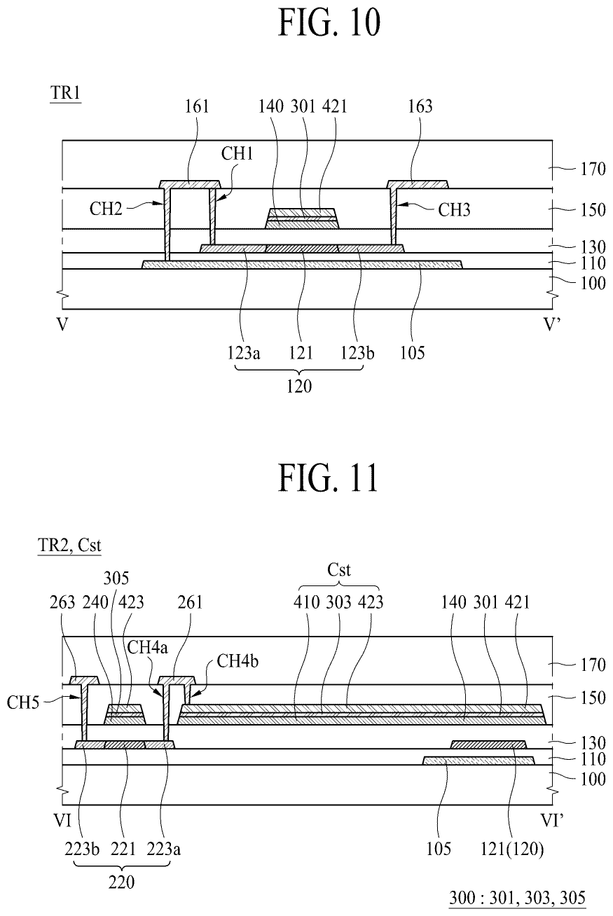

In the first thin film transistor (TR1), the first gate electrode (140), the first metal insulating layer (301) of the metal insulating layer (300), and the first part (421) of the second electrode (420) are formed to overlap with the first active layer (120). In this case, the first gate electrode (140), the first metal insulating layer (301), and the first part (421) can be formed to correspond to each other by being pattern-formed in the same way in one process. Meanwhile, this will be described in more detail with reference to the cross-sectional view of FIG. 10.

In the second thin film transistor (TR2), the second gate electrode (240) and the third metal insulating layer (305) of the metal insulating layer (300), and the upper metal layer (243) can be formed to overlap with the second active layer (220). In this case, the second gate electrode (240), the third metal insulating layer (305), and the upper metal layer (243) can be formed to correspond to each other by being pattern-formed in the same manner in one process.

The storage capacitor (Cst) is formed with the first electrode (410), the second metal insulating layer (303) of the metal insulating layer (300), and the second part (423) of the second electrode (420). In this case, the first electrode (410), the second metal insulating layer (303), and the second part (423) can be formed to correspond to each other by being pattern-formed in the same way in one process. Meanwhile, this will be described in more detail with reference to the cross-sectional view of FIG. 11.

Meanwhile, according to another embodiment of the present invention, by pattern-forming the first gate electrode (140), the first metal insulating layer (301) and the first portion (421) of the first thin film transistor (TR1), the second gate electrode (240), the third metal insulating layer (305) and the upper metal layer (243) of the second thin film transistor (TR2), and the first electrode (410), the second metal insulating layer (303) and the second portion (423) of the storage capacitor (Cst) so as to correspond to each other in one process, the metal insulating layer (300) continuously formed in the first thin film transistor (TR1) and the storage capacitor (Cst) can be manufactured with a small number of processes, thereby reducing the manufacturing time and cost.

FIG. 10 is a cross-sectional view of a first thin film transistor provided on a thin film transistor substrate according to another embodiment of the present invention. In this case, FIG. 10 is related to cross-section V-V′ of FIG. 9. Meanwhile, the embodiment according to FIG. 10 is the same as the embodiment of FIG. 5 except for the first gate electrode, the first metal insulating layer, and the first portion, and therefore, the following description will focus on the different configurations.

As can be seen in FIG. 10, a first thin film transistor (TR1) according to another embodiment of the present invention comprises a first gate electrode (140), a first metal insulating layer (301), and a first portion (421) of the second electrode (420), each of which has one end and the other end corresponding to each other.

The first gate electrode (140), the first metal insulating layer (301), and the first portion (421) can be pattern-formed in the same manner in one process using the same mask after laminating layers for forming their respective configurations. In detail, a material layer for forming the first gate electrode (140) on the gate insulating layer (130) is disposed on the entire surface of the gate insulating layer (130), a material layer for forming the first metal insulating layer (301) is formed on the entire surface of the material layer for forming the first gate electrode (140), and a material layer for forming the first portion (421) is disposed on the entire surface of the material layer for forming the first metal insulating layer (301), and then pattern-formed using the same mask.

Accordingly, one end and the other end of the first gate electrode (140) correspond to one end and the other end of the first metal insulating layer (301), respectively, and can correspond to one end and the other end of the first part (421). Similarly, one end and the other end of the first metal insulating layer (301) can correspond to one end and the other end of the first part (421), respectively.

According to another embodiment of the present invention, by simultaneously forming the first gate electrode (140), the first metal insulating layer (301), and the first portion (421) in the same process, the manufacturing process and manufacturing time can be reduced.

FIG. 11 is a cross-sectional view of a second thin film transistor and a storage capacitor provided on a thin film transistor substrate according to another embodiment of the present invention. In this case, FIG. 11 is a cross-sectional view taken along line VI-VI′ of FIG. 9.

As can be seen in FIG. 11, a second thin film transistor (TR2) according to another embodiment of the present invention comprises a second gate electrode (240), a third metal insulating layer (305), and the upper metal layer (243), each of which has one end and the other end corresponding to each other.

In this case, the third metal insulating layer (305) can be formed in the same layer as the first metal insulating layer (301) provided in the first thin film transistor (TR1) and the second metal insulating layer (303) provided in the storage capacitor (Cst), and the upper metal layer (243) can be formed in the same layer as the first portion (421) of the first thin film transistor (TR1) and the second portion (423) of the storage capacitor (Cst).

The second gate electrode (240), the third metal insulating layer (305), and the upper metal layer (243) of the second thin film transistor (TR2) can be pattern-formed identically in one process using the same mask after laminating layers to form each configuration.

Accordingly, one end and the other end of the second gate electrode (240) can correspond to one end and the other end of the third metal insulating layer (305), respectively, and can correspond to one end and the other end of the upper metal layer (243). Similarly, one end and the other end of the third metal insulating layer (305) can correspond to one end and the other end of the upper metal layer (243), respectively. Meanwhile, the third metal insulating layer (305) and the upper metal layer (243) can be omitted depending on the case.

The storage capacitor (Cst) comprises a first electrode (410), a second metal insulating layer (303), and a second part (423) of a second electrode (420), each of which is provided so that one end and the other end correspond to each other.

The first electrode (410), the second metal insulating layer (303), and the second portion (423) of the storage capacitor (Cst) can be identically pattern-formed in one process using the same mask after laminating layers to form each configuration.

Accordingly, one end and the other end of the first electrode (410) correspond to one end and the other end of the second metal insulating layer (303), respectively, and can correspond to one end and the other end of the second part (423). Similarly, one end and the other end of the second metal insulating layer (303) can correspond to one end and the other end of the second part (423), respectively.

According to another embodiment of the present invention, the second gate electrode (240), the third metal insulating layer (305) and the upper metal layer (243) of the second thin film transistor (TR2) and the first electrode (410), the second metal insulating layer (303) and the second portion (423) of the storage capacitor (Cst) are formed simultaneously in the same process, thereby reducing the manufacturing process and manufacturing time.

Meanwhile, the method of forming the second gate electrode (240), the third metal insulating layer (305) and the upper metal layer (243) of the second thin film transistor (TR2), and the first electrode (410), the second metal insulating layer (303) and the second portion (423) of the storage capacitor (Cst) is the same as the method of forming the first gate electrode (140), the first metal insulating layer (305) and the first portion (421) of the first thin film transistor (TR1), so a repeated description will be omitted or may be briefly provided.

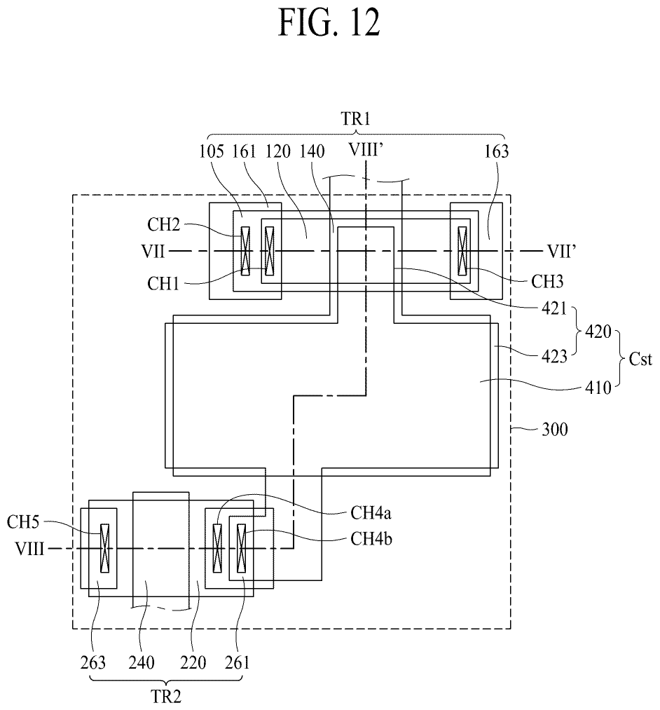

FIG. 12 is a plan view of a thin film transistor substrate according to another embodiment of the present invention. Meanwhile, the embodiment of FIG. 12 is identical to the embodiment of FIG. 4 except for the configuration of the metal insulating layer, so the following description will focus on the different configuration.

As can be seen in FIG. 12, according to another embodiment of the present invention, the metal insulating layer (300) may not be separately pattern-formed. By being formed in this manner, the metal insulating layer (300) can be provided to overlap the entire area where the first thin film transistor (TR1), the second thin film transistor (TR2), and the storage capacitor (Cst) are formed.

In this case, since the metal insulating layer (300) is provided over the entire area where the first thin film transistor (TR1), the second thin film transistor (TR2), and the storage capacitor (Cst) are formed without forming a separate pattern, the number of processes can be reduced, and thus the manufacturing cost can be reduced.

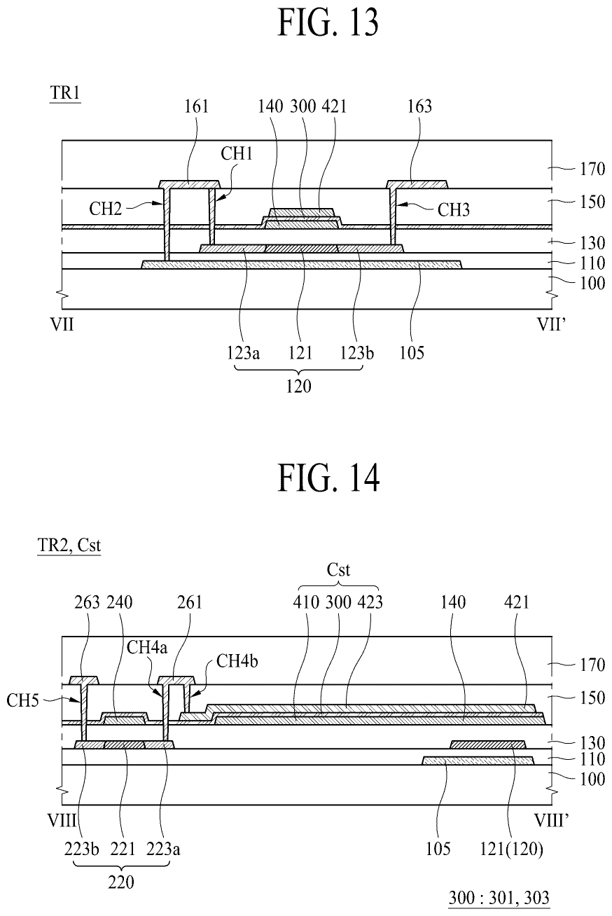

FIG. 13 is a cross-sectional view of a first thin film transistor provided on a thin film transistor substrate according to another embodiment of the present invention. In this case, FIG. 13 is related to cross-section VII-VII′ of FIG. 12. Meanwhile, the embodiment of FIG. 13 is the same as the embodiment of FIG. 5 except for the configuration of the metal insulating layer, so the following description will focus on the different configuration.

As can be seen in FIG. 13, a first thin film transistor (TR1) according to another embodiment of the present invention comprises a metal insulating layer (300) formed on the entire surface of the substrate (100). The metal insulating layer (300) can overlap with the first gate electrode (140) and the first portion (421).

The metal insulating layer (300) can overlap with the first active layer (120). According to another embodiment of the present invention, the metal insulating layer (300) can overlap with the entire first channel portion (121), the first connection portion (123a), and the second connection portion (123b) of the first active layer (120). By forming in this manner, it is possible to prevent hydrogen generated in a process of manufacturing a thin film transistor substrate and/or a display apparatus according to an embodiment of the present invention from flowing into the first active layer (120).

Since the metal insulating layer (300) is formed on the entire surface of the substrate (100), the first contact hole (CH1) and the second contact hole (CH2) provided to electrically connect the light-shielding layer (105), the first connecting portion (123a) of the first active layer (120), and the first source electrode (161) can be provided to penetrate a portion of the metal insulating layer (300). Similarly, the third contact hole (CH3) provided to electrically connect the second connecting portion (123b) of the first active layer (120) and the first drain electrode (163) can be provided to penetrate another portion of the metal insulating layer (300).

FIG. 14 is a cross-sectional view of a second thin film transistor and a storage capacitor provided on a thin film transistor substrate according to another embodiment of the present invention. In this case, FIG. 14 is a cross-sectional view taken along line VIII-VIII′ of FIG. 12. Meanwhile, the embodiment of FIG. 14 is identical to the embodiment of FIG. 6 except for the configuration of the metal insulating layer, so the following description will focus on the different configuration.

As can be seen in FIG. 14, according to another embodiment of the present invention, the metal insulating layer (300) can be provided so as to share both the area where the second thin film transistor (TR2) and the storage capacitor (Cst) are formed.

In detail, in the region where the second thin film transistor (TR2) is formed, the metal insulating layer (300) can be provided on the second gate electrode (240). In this case, since the metal insulating layer (300) is formed over the entire surface of the substrate (100), the 4-1st contact hole (CH4a) provided to electrically connect the third connecting portion (223a) of the second active layer (220) and the second source electrode (261) can be provided to penetrate a portion of the metal insulating layer (300), and similarly, the 5th contact hole (CH5) provided to electrically connect the fourth connecting portion (223b) of the second active layer (220) and the second drain electrode (263) can be provided to penetrate another portion of the metal insulating layer (300).

In the region where the storage capacitor (Cst) is formed, the metal insulating layer (300) can be provided between the first electrode (410) and the second portion (423) of the second electrode (420). In this case, the metal insulating layer (300) can be provided to cover the first electrode (410) and can be in contact with a portion of the upper surface of the gate insulating layer (130) where the first electrode (410) is not provided.

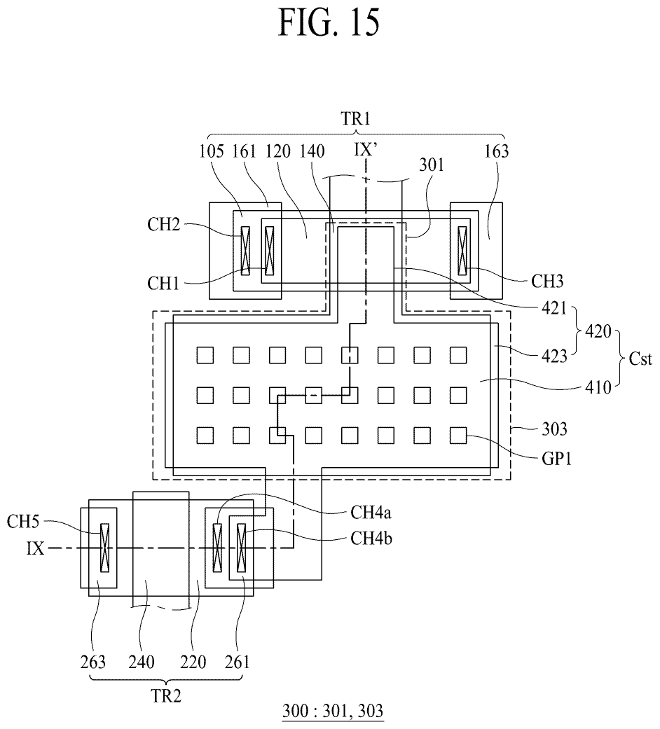

FIG. 15 is a plan view of a thin film transistor substrate according to another embodiment of the present invention. Meanwhile, the embodiment of FIG. 15 is identical to the embodiment of FIG. 4 except for a plurality of first grooves, and therefore, the following description will focus on the different configurations.

As can be seen from FIG. 15, according to another embodiment of the present invention, the storage capacitor (Cst) can be formed by including a plurality of first groove portions (GP1). In detail, the plurality of first groove portions (GP1) can be formed on the first electrode (410) of the storage capacitor (Cst1). By including the plurality of first groove portions (GP1), the electrostatic capacitance of the storage capacitor (Cst) can be further improved.

Meanwhile, in FIG. 15, only the plurality of first grooves (GP1) are shown in an 8×3 arrangement, but this is not limited to the first grooves (GP1) and the plurality of first grooves (GP1) can be arranged in various ways depending on the level of technology in the art.

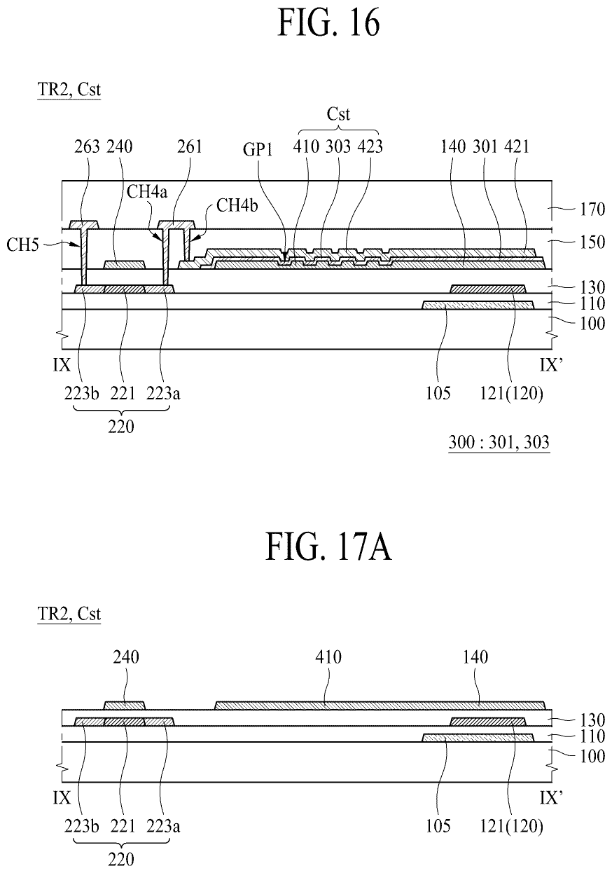

FIG. 16 is a cross-sectional view of a second thin film transistor and a storage capacitor provided on a thin film transistor substrate according to another embodiment of the present invention. In this case, FIG. 16 is taken along cross-section IX-IX′ of FIG. 15. Meanwhile, the embodiment of FIG. 16 is identical to the embodiment of FIG. 6 except for a plurality of first grooves, and therefore, the following description will focus on different configurations.

As can be seen in FIG. 16, the storage capacitor (Cst) can be formed by including a plurality of first grooves (GP1). In detail, the plurality of first grooves (GP1) can be formed by etching a portion of the upper surface of the first electrode (410). Accordingly, the first electrode (410) can be formed to be curved by the plurality of first grooves (GP1). In detail, the upper surface of the first electrode (410) can be formed to be curved by the plurality of first grooves (GP1).

The second metal insulating layer (303) can be provided on the first electrode (410) of the storage capacitor (Cst). In detail, the second metal insulating layer (303) can be formed on the plurality of first groove portions (GP1) of the first electrode (410). Accordingly, a part of the second metal insulating layer (303) can be formed inside the plurality of first groove portions (GP1), and accordingly, the second metal insulating layer (303) can be formed to be curved along the plurality of first groove portions (GP1).

The second part (423) of the second electrode (420) can be disposed on the second metal insulating layer (303). In detail, a part of the second part (423) can be formed on the plurality of first grooves (GP1) of the first electrode (410). Accordingly, a part of the second part (423) can be formed to be curved along the curved shape of the plurality of first grooves (GP1). In this case, the curved shape can mean a shape created by repeatedly forming concave and convex parts.

According to another embodiment of the present invention, the first electrode (410), the second metal insulating layer (303), and the second portion (423) are formed to be curved, so that the area where the first electrode (410), the second metal insulating layer (303), and the second portion (423) overlap each other increases, thereby improving the electrostatic capacitance of the storage capacitor (Cst).

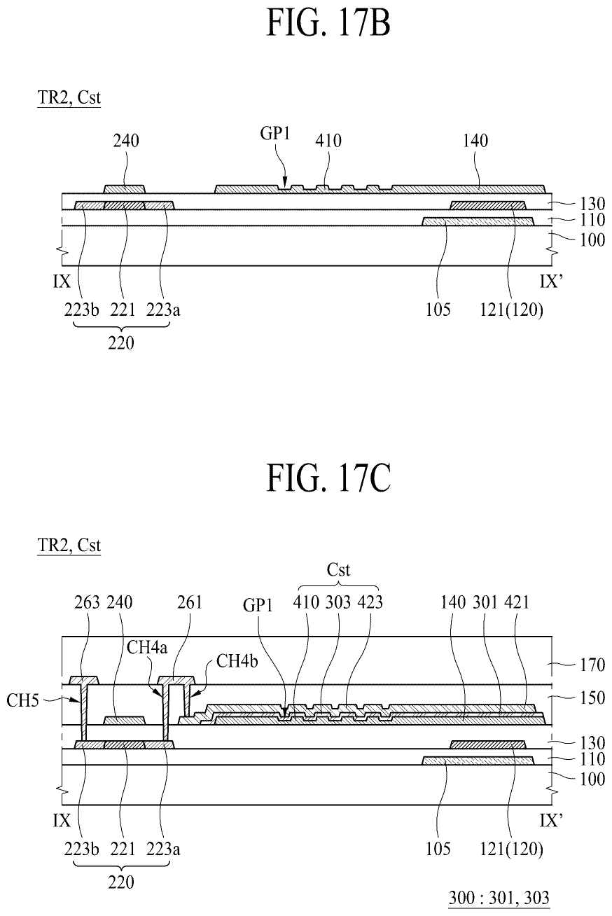

FIGS. 17A to 17C are process cross-sectional views of a second thin film transistor and a storage capacitor provided on a thin film transistor substrate according to another embodiment of the present invention. In this case, FIGS. 17A to 17C are cross-sectional views corresponding to IX-IX′ of FIG. 15. Meanwhile, FIGS. 17A to 17C are process cross-sectional views corresponding to the embodiment of FIG. 16, and thus, the same reference numerals are assigned to the same components, and repeated descriptions will be omitted or may be briefly provided.

First, as can be seen in FIG. 17A, the light-shielding layer (105), the buffer layer (110), the first channel portion (121 (120)) and the second active layer (220), the gate insulating layer (130), the second gate electrode (240), the first electrode (410) and the first gate electrode (140) are sequentially formed on the substrate (100).

Next, as can be seen in FIG. 17B, a portion of the upper surface of the first electrode (410) is etched to form a plurality of first grooves (GP1).

Finally, as can be seen in FIG. 17C, when the metal insulating layer (300), In detail, the first metal insulating layer (301) and the second metal insulating layer (303), the second electrode (420), In detail, the first portion (421) and the second portion (423), the interlayer insulating layer (150), the second source electrode (261), the second drain electrode (263), and the planarization layer (170) are sequentially formed on the first electrode (410) on which the plurality of first grooves (GP1) are formed, the second thin film transistor (TR2) and the storage capacitor (Cst) according to another embodiment of the present invention can be implemented.

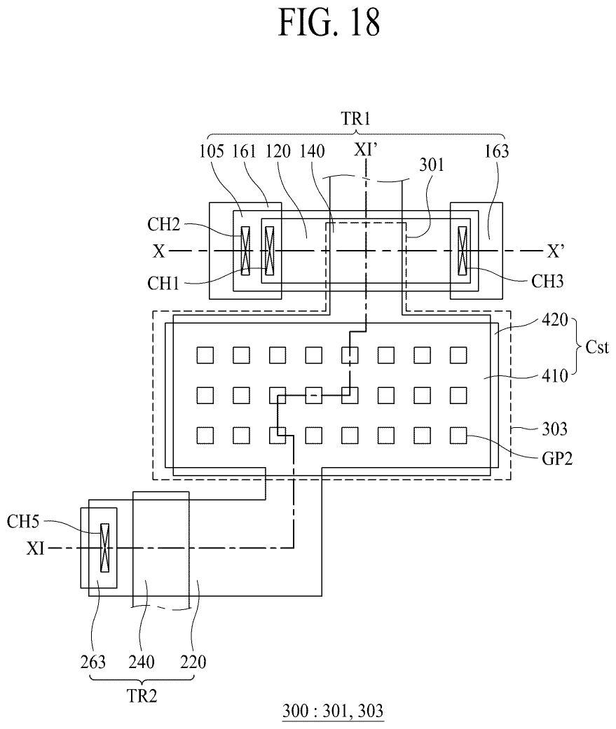

FIG. 18 is a plan view of a thin film transistor substrate according to another embodiment of the present invention.

As can be seen from FIG. 18, a thin film transistor substrate according to another embodiment of the present invention comprises a first thin film transistor (TR1), a second thin film transistor (TR2), and a storage capacitor (Cst) provided between the first thin film transistor (TR1) and the second thin film transistor (TR2).

The first thin film transistor (TR1) includes a light-shielding layer (105), a first active layer (120), a first gate electrode (140), a first source electrode (161), and a first drain electrode (163).

The above-described light-shielding layer (105) can extend in a first direction, for example, a horizontal direction. The light-shielding layer (105) can be provided to overlap with the first active layer (120). In detail, the light-shielding layer (105) can be provided to overlap with the entire first active layer (120). However, the present invention is not limited thereto.

The above-mentioned light-shielding layer (105) can be electrically connected to the first source electrode (161) through the second contact hole (CH2).

The first active layer (120) can extend in a first direction, for example, a horizontal direction.

The first gate electrode (140) can extend in a second direction, for example, a vertical direction, and can be provided to overlap the first active layer (120). In this case, the second direction can be a direction orthogonal to the first direction.

The first source electrode (161) and the first drain electrode (163) can be provided on one side and the other side of the first active layer (120), respectively. For example, the first source electrode (161) can be provided on the left side of the first active layer (120) and can be electrically connected to the first active layer (120) through a first contact hole (CH1), and the first drain electrode (163) can be provided on the right side of the first active layer (120) and can be electrically connected to the first active layer (120) through a third contact hole (CH3).

The second thin film transistor (TR2) includes a second active layer (220), a second gate electrode (240), and a second drain electrode (263).

The second active layer (220) can extend in a first direction, for example, a horizontal direction.

According to another embodiment of the present invention, one side of the second active layer (220), for example, the right side, can be extended to form the second electrode (420) of the storage capacitor (Cst). In other words, one side of the second active layer (220) can be formed integrally with the second electrode (420) of the storage capacitor (Cst).

The second gate electrode (240) can extend in a second direction, for example, a vertical direction, and can be provided to overlap a portion of the second active layer (220).

The second drain electrode (263) can be provided on the other side of the second active layer (220). For example, the second drain electrode (263) can be provided on the left side of the second active layer (220) and can be electrically connected to the second active layer (220) through the fifth contact hole (CH5).

The storage capacitor (Cst) comprises a first electrode (410), a second electrode (420), and a metal insulating layer (300) provided between the first electrode (410) and the second electrode (420).

The first electrode (410) and the second electrode (420) can be spaced apart from each other so as to overlap each other with the metal insulating layer (300) therebetween. The first electrode (410) and the second electrode (420) can be spaced apart from each other so as to overlap each other in some areas, so that capacitance can be formed by different electric fields applied to each of the first electrode (410) and the second electrode (420).

The first electrode (410) can be a portion extending from one side of the second active layer (220) of the second thin film transistor (TR2), as described above.

According to another embodiment of the present invention, the first electrode (410) can be formed integrally with the second active layer (220) of the second thin film transistor (TR2), and by being formed in this manner, the first electrode (410) of the storage capacitor (Cst) and the second active layer (220) of the second thin film transistor (TR2) can be formed using the same material in the same process.

According to another embodiment of the present invention, the storage capacitor (Cst) can be formed by including a plurality of second groove portions (GP2). In detail, the plurality of second groove portions (GP2) can be formed on the first electrode (410) of the storage capacitor (Cst1). By including the plurality of second groove portions (GP2), the electrostatic capacitance of the storage capacitor (Cst) can be further improved.

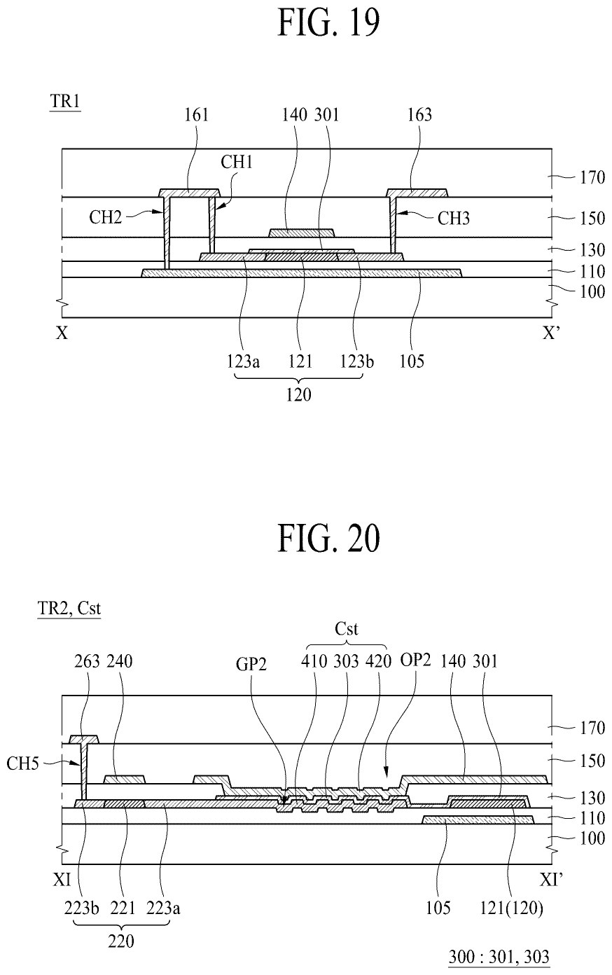

Meanwhile, in FIG. 19, only the plurality of second grooves (GP2) are shown in an 8×3 arrangement, but this is not limited to the arrangement, and the plurality of second grooves (GP2) can be arranged in various ways depending on the level of technology in the art.

The second electrode (420) can be a portion from which the first gate electrode (140) of the first thin film transistor (TR1) extends. In other words, the second electrode (420) of the storage capacitor (Cst) can be configured by extending the first gate electrode (140) of the first thin film transistor (TR1). Alternatively, the second electrode (420) of the storage capacitor (Cst) can be formed integrally with the first gate electrode (140) of the first thin film transistor (TR1).

According to another embodiment of the present invention, the second electrode (420) can be formed integrally with the first gate electrode (140) of the first thin film transistor (TR1), and by being formed in this manner, the second electrode (420) of the storage capacitor (Cst) and the first gate electrode (140) of the first thin film transistor (TR1) can be formed using the same material in the same process.

The metal insulating layer (300) can be provided continuously in an area where the first thin film transistor (TR1) and the storage capacitor (Cst) are formed. In detail, the metal insulating layer (300) includes a first metal insulating layer (301) and a second metal insulating layer (303), and the first metal insulating layer (301) and the second metal insulating layer (303) can be provided continuously with each other.

The first metal insulating layer (301) can overlap a portion of the first thin film transistor (TR1). In detail, the first metal insulating layer (301) can overlap the first active layer (120) and the first gate electrode (140).

The second metal insulating layer (303) can be provided to overlap the first electrode (410) and the second electrode (420). The second metal insulating layer (303) can be provided between the first electrode (410) and the second electrode (420), so that when different electric fields are applied to the first electrode (410) and the second electrode (420), capacitance can be formed in the storage capacitor (Cst).

FIG. 19 is a cross-sectional view of a first thin film transistor provided on a thin film transistor substrate according to another embodiment of the present invention. In this case, FIG. 19 is related to cross-section X-X′ of FIG. 18. Meanwhile, the embodiment of FIG. 19 is identical to the embodiment of FIG. 5 except for the first metal insulating layer and the second portion (see 421 of FIG. 5), and therefore, the following description will focus on different configurations.

As can be seen in FIG. 19, a first thin film transistor (TR1) according to another embodiment of the present invention includes a substrate (100), a light-shielding layer (105), a buffer layer (110), a first active layer (120), a first metal insulating layer (301), a gate insulating layer (130), a first gate electrode (140), an interlayer insulating layer (150), a first source electrode (161), a first drain electrode (162), and a planarizing layer (170). In the embodiment of FIG. 19, unlike the embodiment of FIG. 5, the first metal insulating layer (301) is provided so as to be in contact with the first active layer (120).

The first metal insulating layer (301) can be provided to overlap the first active layer (120) and the first gate electrode (140), and according to another embodiment of the present invention, the first metal insulating layer (301) can be provided between the first active layer (120) and the first gate electrode (140). In detail, the first metal insulating layer (301) can be in contact with a portion of the upper surface of the first active layer (120). More specifically, the first metal insulating layer (301) can overlap the entire upper surface of the first channel portion (121) and can overlap a portion of the upper surfaces of the first connection portion (123a) and the second connection portion (123b). However, the present invention is not limited thereto.

According to another embodiment of the present invention, the first metal insulating layer (301) is provided so as to be in contact with the first channel portion (121) of the first active layer (120), thereby preventing hydrogen generated during the process of manufacturing the thin film transistor substrate and the display apparatus according to another embodiment of the present invention from flowing into the first active layer (120). For example, when a heat treatment process is performed during the process of forming a planarization layer or an encapsulating layer provided on the first metal insulating layer (301), a large amount of hydrogen can flow into the first channel portion (121) of the first active layer (120) from the upper surface of the thin film transistor substrate and/or the display apparatus. If hydrogen flows into the first channel portion (121), the first channel portion (121) can partially become conductive, thereby deteriorating the device characteristics of the first thin film transistor (TR1). In this case, the metal insulating layer (130) is provided to cover the first gate electrode (140) and overlap with the first channel portion (121) of the first active layer (120), so that hydrogen generated through the heat treatment process can be captured by the first metal insulating layer (301) before reaching the first channel portion (121), thereby preventing the semiconductor characteristics of the first channel portion (121) from being deteriorated.

Meanwhile, since the first metal insulating layer (301) according to the embodiment of FIG. 19 is the same as the first metal insulating layer (301) according to the embodiment of FIG. 2, a repeated description thereof will be omitted or may be briefly provided.

The gate insulating layer (130) can be disposed on the first active layer (120) and the first metal insulating layer (301).

FIG. 20 is a cross-sectional view of a second thin film transistor and a storage capacitor provided on a thin film transistor substrate according to another embodiment of the present invention. In this case, FIG. 20 is a cross-sectional view taken along line XI-XI′ of FIG. 18. Meanwhile, the embodiment of FIG. 20 is the same as the embodiment of FIG. 6 except for the configuration of the buffer layer, the second thin film transistor, and the storage capacitor, and therefore, the following description will focus on the different configurations.

As can be seen from FIG. 20, a thin film transistor substrate according to another embodiment of the present invention comprises a second thin film transistor (TR2) and a storage capacitor (Cst). In this case, the second thin film transistor (TR2) and the storage capacitor (Cst) can share the second active layer (220).

The second thin film transistor (TR2) includes a second active layer (220), a second gate electrode (240), and a second drain electrode (263) provided on the buffer layer (110). The second active layer (220) includes a second channel portion (221), a third connection portion (223a) provided on one side of the second channel portion (221), for example, on the right side, and a fourth connection portion (223b) provided on the other side of the second channel portion (221), for example, on the left side.

The third connecting portion (223a) can function as a source electrode because it has higher conductivity than the second channel portion (221), and the fourth connecting portion (223b) can be electrically connected to the second drain electrode (263) through the fifth contact hole (CH5).

According to another embodiment of the present invention, the third connecting portion (223a) of the second active layer (220) can extend to one side, for example, to the right, thereby forming the first electrode (410) of the storage capacitor (Cst).

The storage capacitor (Cst) includes the first electrode (410), the second metal insulating layer (303), and the second electrode (420).

According to another embodiment of the present invention, a plurality of second grooves (GP2) can be formed in the buffer layer (110). By forming in this manner, a portion of the upper surface of the buffer layer (110) can have a curved shape due to the plurality of second grooves (GP2).

The first electrode (410) is disposed on the buffer layer (110).

According to another embodiment of the present invention, a part of the first electrode (410) can be disposed on the buffer layer (110) in which the plurality of second grooves (GP2) are formed. Accordingly, a portion of the first electrode (410) can be formed to be curved along the plurality of second grooves (GP2).

The second metal insulating layer (303) can be disposed on the first electrode (410) of the storage capacitor (Cst). In detail, the second metal insulating layer (303) can be formed to overlap with the plurality of second groove portions (GP2) of the buffer layer (110). Accordingly, a portion of the second metal insulating layer (303) can be formed to be curved along the curved shape of the first electrode (410).

The second part (423) of the second electrode (420) can be disposed on the second metal insulating layer (303).

The second electrode (420) can be formed using the same material in the same layer as the first gate electrode (140) of the first thin film transistor (TR1) and/or the second gate electrode (240) of the second thin film transistor (TR2), but is not limited thereto. According to another embodiment of the present invention, in order to form the second electrode (420) on the second metal insulating layer (303), a second open portion (OP2) can be provided in the gate insulating layer (130). In this case, a part of the upper surface of the second metal insulating layer (303) can be exposed by the second open portion (OP2), and through this, a part of the upper surface of the second metal insulating layer (303) and the second electrode (420) can come into contact with each other.

According to another embodiment of the present invention, a part of the second electrode (240) can be formed on the plurality of second grooves (GP2) of the first electrode (410). Accordingly, a part of the second portion (423) can be formed to be curved along the curved shape of the plurality of second grooves (GP2).

According to another embodiment of the present invention, the first electrode (410), the second metal insulating layer (303), and the second portion (423) are formed to be curved, so that the area where the first electrode (410), the second metal insulating layer (303), and the second portion (423) overlap each other increases, thereby improving the electrostatic capacitance of the storage capacitor (Cst).

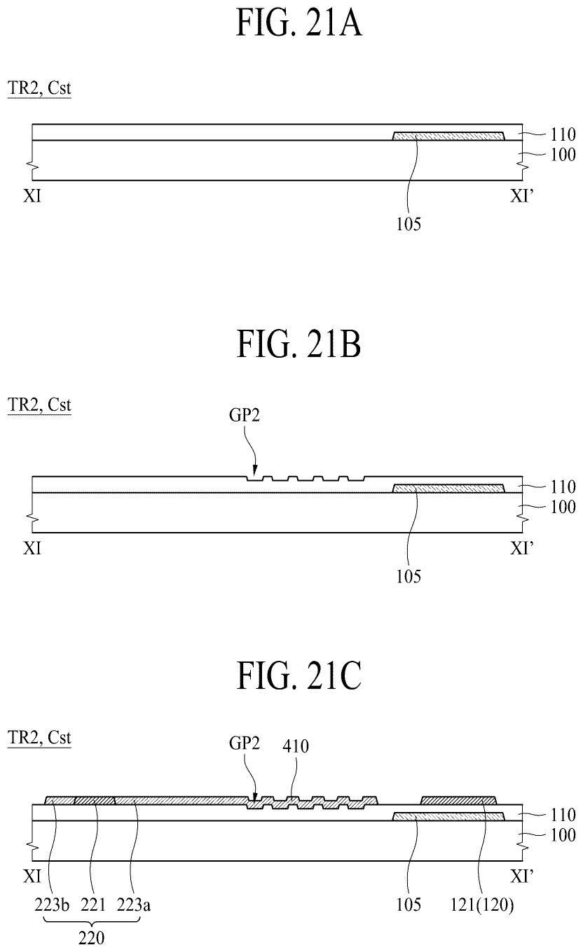

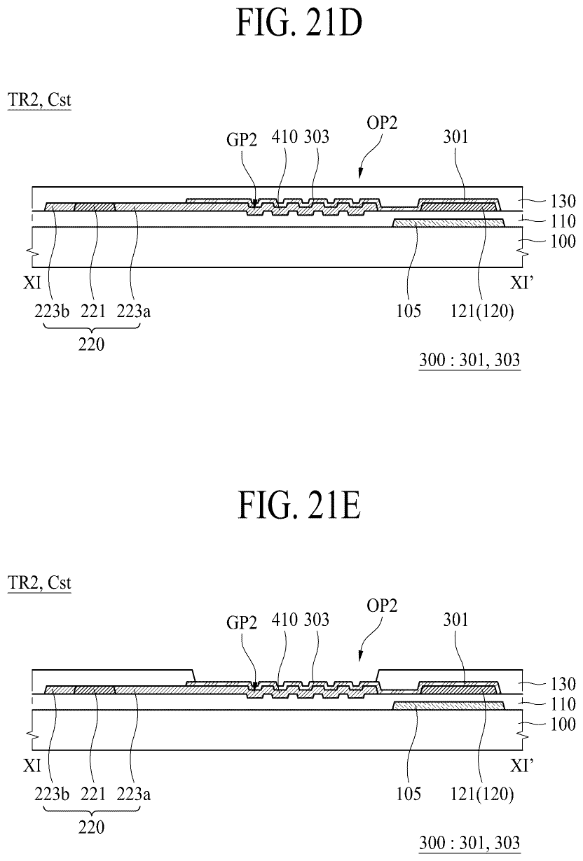

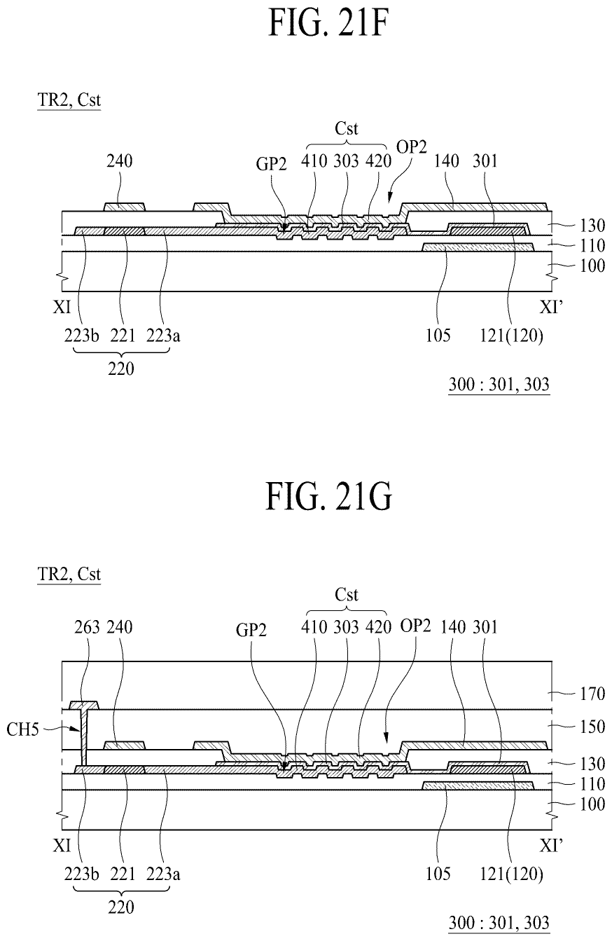

FIGS. 21A to 21G are process cross-sectional views of a second thin film transistor and a storage capacitor provided on a thin film transistor substrate according to another embodiment of the present invention. In this case, FIGS. 21A to 21G are cross-sectional views XI-XI′ of FIG. 18. Meanwhile, FIGS. 21A to 21G are process cross-sectional views of the embodiment of FIG. 20, and thus, the same reference numerals are given to the same components, and repeated descriptions will be omitted or may be briefly provided.

First, as can be seen in FIG. 21A, the light-shielding layer (105) and the buffer layer (110) are sequentially formed on the substrate (100).

Next, as can be seen in FIG. 21B, a portion of the buffer layer (110) can be etched to form the plurality of second grooves (GP2). In detail, the plurality of second grooves (GP2) can be formed by etching a portion of the upper surface of the buffer layer (110). Meanwhile, in FIG. 21b, the plurality of second grooves (GP2) are formed by etching a portion of the upper surface of the buffer layer (110) to an extent that the upper surface of the substrate (100) is not exposed, but is not limited thereto.

Next, as can be seen in FIG. 21C, the first active layer (120) and the second active layer (220) can be disposed on the buffer layer (110). Although not specifically shown, the first active layer (120) and the second active layer (220) can undergo a process of conducting using a resist pattern as a mask. When the conducting process is performed, the first channel portion (121) is formed in the first active layer (120), and the second channel portion (221), the third connection portion (223a), and the fourth connection portion (223b) are formed in the second active layer (220).

According to another embodiment of the present invention, the third connecting portion (223a) of the second active layer (220) can be formed in the plurality of second groove portions (GP2) of the buffer layer (110), thereby being formed to be curved along the curved shape of the plurality of second groove portions (GP2).

Next, as can be seen in FIG. 21D, the metal insulating layer (300) and the gate insulating layer (130) are formed on the first active layer (120) and the second active layer (220). In this case, the metal insulating layer (300) is provided to cover a portion of the upper surfaces of the first active layer (120) and the second active layer (220), and can be continuously provided in the region between the first active layer (120) and the second active layer (220).

In this case, the metal insulating layer (300) formed on the first active layer (120) becomes the first metal insulating layer (301), and the metal insulating layer (300) formed on the second active layer (220) becomes the second metal insulating layer (303). Furthermore, a part of the metal insulating layer (300) continuously formed between the first metal insulating layer (301) and the second metal insulating layer (303) can come into contact with the upper surface of the buffer layer (110).

According to another embodiment of the present invention, the second metal insulating film (303) can be formed in the plurality of second grooves (GP2), thereby being provided to be curved along the plurality of second grooves (GP2).

Next, as can be seen in FIG. 21E, a part of the gate insulating layer (130) can be etched to form the second open portion (OP2) so that a part of the upper surface of the second metal insulating layer (303) is exposed. By the second open portion (OP2), a part of the upper surface of the second metal insulating layer (303) can be exposed to the outside.

Next, as can be seen in FIG. 21F, the first gate electrode (140), the second electrode (420), and the second gate electrode (240) can be pattern-formed on the gate insulating layer (130).

The first gate electrode (140) can be provided to overlap with the first active layer (120).

The second electrode (420) is provided continuously with the first gate electrode (140), and the second electrode (420) is formed in the second open portion (OP2), so that it can come into contact with a part of the upper surface of the second metal insulating layer (303) exposed to the outside through the second open portion (OP2). By being formed in this manner, the storage capacitor (Cst) can be formed by the first electrode (410), the second metal insulating layer (303), and the second electrode (420).

The second electrode (420) can be formed on the plurality of second grooves (GP2), thereby being provided to be curved along the plurality of second grooves (GP2).

The second gate electrode (240) can be provided to overlap with the second active layer (220). In detail, the second gate electrode (240) can be formed to overlap with the second channel portion (221) of the second active layer (220).

Finally, as can be seen in FIG. 21G, an interlayer insulating layer (150) is formed on the first gate electrode (140), the second electrode (420), and the second gate electrode (240), a portion of the interlayer insulating layer (150) is etched to form a fifth contact hole (CH5), a second drain electrode (263) is formed that is connected to the fourth connecting portion (223b) of the second active layer (220) through the fifth contact hole (CH5), and a planarization layer (170) is formed on the interlayer insulating layer (150) and the second drain electrode (263), thereby implementing a thin film transistor substrate according to another embodiment of the present invention.

FIG. 22 is a cross-sectional view of a thin film display apparatus according to one embodiment of the present invention.

As can be seen in FIG. 22, a display apparatus according to one embodiment of the present invention includes a substrate (100), a buffer layer (110), a first active layer (120), a gate insulating layer (130), a first gate electrode (140), a first metal insulating layer (501), a first portion (421), an interlayer insulating layer (150), a first source electrode (161), a first drain electrode (162), a planarization layer (170), a first electrode (510), a bank layer (520), a light-emitting layer (530), and a second electrode (540).

Meanwhile, the substrate (100), the buffer layer (110), the first active layer (120), the gate insulating layer (130), the first gate electrode (140), the first metal insulating layer (501), the first portion (421), the interlayer insulating layer (150), the first source electrode (161), the first drain electrode (162), and the planarization layer (170) are the same as those in the above-described embodiments, so only the different configurations will be described below.

The flattening layer (170) is provided with a sixth contact hole (CH6), so that the first source electrode (161) is exposed by the sixth contact hole (CH6). However, depending on the case, the first drain electrode (163) can be exposed by the sixth contact hole (CH6).

The first electrode (510) is disposed on the planarization layer (170) and is connected to the first source electrode (161) or the first drain electrode (163) through the sixth contact hole (CH6). The first electrode (510) can function as an anode.

The bank layer (520) is provided to cover the edge of the first electrode (510) and define a light-emitting area. Accordingly, the upper surface area of the first electrode (510) that is exposed and not covered by the bank layer (520) becomes a light-emitting area.

The above-described light-emitting layer (530) is disposed on the first electrode (510). The light-emitting layer (530) can be formed by including red, green, and blue light-emitting layers patterned for each pixel, or can be formed by a white light-emitting layer connected to all pixels. When the light-emitting layer (530) is formed by a white light-emitting layer, the light-emitting layer (530) can be formed by including, for example, a first stack including a blue light-emitting layer, for example, a second stack including a yellow-green light-emitting layer, and a charge generation layer provided between the first stack and the second stack, but is not necessarily limited thereto.

The second electrode (540) is disposed on the light-emitting layer (530). The second electrode (540) can function as a cathode.

A sealing layer can be additionally formed on the second electrode (540) to prevent the penetration of moisture or oxygen.

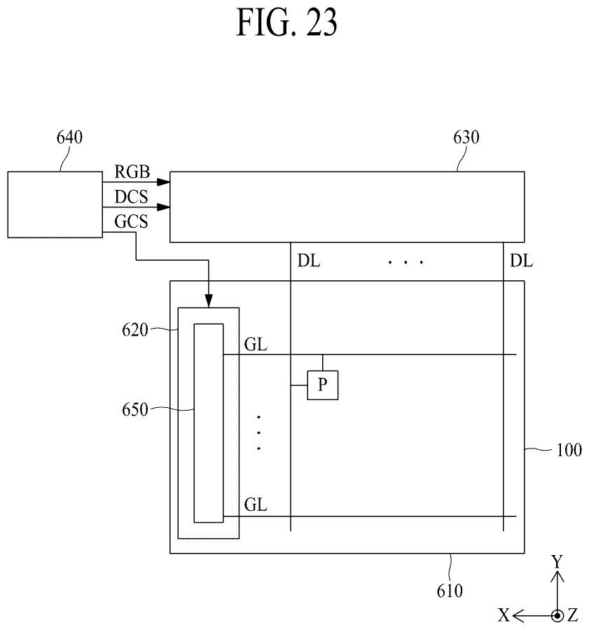

FIG. 23 is a schematic plan view showing a display apparatus according to one embodiment of the present invention.

As can be seen in FIG. 23, a display apparatus according to one embodiment of the present invention can include a display panel (610), a gate driver (620), a data driver (630), and a control unit (640).

The display panel (610) includes gate lines (GL) and data lines (DL), and pixels (P) are arranged at intersections of the gate lines (GL) and data lines (DL). An image is displayed by driving the pixels (P). The gate lines (GL), data lines (DL), and pixels (P) can be arranged on a substrate (100).

The control unit (640) controls the gate driver (620) and the data driver (630). The control unit (640) outputs a gate control signal (GCS) for controlling the gate driver (620) and a data control signal (DCS) for controlling the data driver (630) using a signal supplied from an external system. In addition, the control unit (640) samples input image data input from an external system, rearranges it, and supplies rearranged digital image data (RGB) to the data driver (630).

The gate control signal (GCS) includes a gate start pulse (GSP), a gate shift clock (GSC), a gate output enable signal (GOE), a start signal (Vst), and a gate clock (GCLK). In addition, the gate control signal (GCS) can include control signals for controlling a shift register.

The data control signal (DCS) includes a source start pulse (SSP), a source shift clock signal (SSC), a source output enable signal (SOE), a polarity control signal (POL), etc.

The data driver (630) supplies data voltage to the data lines (DL) of the display panel (610). In detail, the data driver (630) converts image data (RGB) input from the control unit (640) into analog data voltage and supplies the data voltage to the data lines (DL).

The gate driver (620) can be mounted on the display panel (610). In this way, a structure in which the gate driver (620) is directly mounted on the display panel (610) is called a gate in panel (GIP) structure. In detail, in the gate in panel (GIP) structure, the gate driver (620) can be placed on the substrate (100).

The gate driver (620) can include a shift register (650).

The shift register (650) sequentially supplies gate pulses to gate lines (GL) for one frame using a start signal and gate clock transmitted from the control unit (640). Here, one frame refers to a period during which one image is output through the display panel (610). The gate pulse has a turn-on voltage capable of turning on a switching element (thin film transistor) arranged in a pixel (P).

In addition, the shift register (650) supplies a gate off signal capable of turning off the switching element to the gate line (GL) during the remaining period during which the gate pulse is not supplied during one frame. The gate pulse and the gate off signal can be collectively referred to as a gate signal (GS).

Although the embodiments of the present invention have been described in more detail with reference to the attached drawings, the present invention is not necessarily limited to these embodiments, and various modifications can be made without departing from the technical idea of the present invention. Accordingly, the embodiments disclosed in the present invention are not intended to limit the technical idea of the present invention, but to explain it, and the scope of the technical idea of the present invention is not limited by these embodiments. Therefore, it should be understood that the embodiments described are exemplary in all aspects and not restrictive. The protection scope of the present invention should be interpreted by the claims, and all technical ideas within a scope equivalent thereto should be interpreted as being included in the scope of the rights of the present invention.

According to one or more embodiments of the present invention, the metal insulating film provided in the driving thin-film transistor can prevent hydrogen, which can be generated during the process of forming an inorganic or organic film, from entering the active layer of the driving thin-film transistor.

According to embodiments of the present invention, the metal insulating film provided in the driving thin-film transistor can minimize hydrogen infiltration into the active layer, thereby preventing the deterioration of the device characteristics of the driving thin-film transistor.

According to embodiments of the present invention, a storage capacitor having an improved capacitance can be realized by a metal insulating film having a high dielectric constant that is formed continuously on the driving thin film transistor and the storage capacitor.

According to embodiments of the present invention, by forming grooves on one of the first or second electrodes of the storage capacitor and providing it in a curved shape, the surface area between the first and second electrodes can be increased, thereby enhancing the capacitance of the storage capacitor.

According to embodiments of the present invention, the storage capacitor with enhanced capacitance improves the gray scale expression of the driving thin-film transistor, enabling the implementation of a high contrast ratio.

The effects of the present invention are not limited to those mentioned above, and other effects not explicitly stated can be clearly understood by those skilled in the art from the above descriptions.

What is claimed is:

1. A thin film transistor substrate comprising:
a base substrate;
a first thin film transistor disposed on the base substrate; and
a storage capacitor disposed on the base substrate,
wherein the first thin film transistor comprises:
a first active layer disposed on the base substrate and including an oxide semiconductor material;
a first gate electrode disposed on the first active layer; and
a metal insulating layer overlapping the first active layer and the first gate electrode,
wherein the storage capacitor comprises:
a first electrode disposed on the base substrate;
a second electrode disposed on the first electrode; and
the metal insulating layer provided between the fist electrode and the second electrode, and
wherein a resistivity of the metal insulating layer is higher than a resistivity of the first active layer.

2. The thin film transistor substrate of claim 1,
wherein the metal insulating layer comprises at least one of an IGO (InGaO)-based semiconductor material, an IGZO (InGaZnO)-based semiconductor material, an IGZTO (InGaZnSnO)-based oxide semiconductor material, a GZTO (GaZnSnO)-based oxide semiconductor material, a GZO (GaZnO)-based semiconductor material, a GO (GaO)-based semiconductor material, a ZO (ZnO)-based semiconductor material, a titanium oxide (TiO) semiconductor material, an aluminum oxide (AlO) semiconductor material, and a molybdenum oxide (MoO) semiconductor material.

3. The thin film transistor substrate of claim 1,
wherein the metal insulating layer is disposed on the first gate electrode, and
wherein the first gate electrode is extended to form the first electrode of the storage capacitor.

4. The thin film transistor substrate of claim 3,
wherein the metal insulating layer is in contact with a upper surface and one side surface of the first gate electrode.

5. The thin film transistor substrate of claim 4, the first thin film transistor further comprising:
an interlayer insulating layer disposed on the metal insulating layer and having a first opening; and
the second electrode disposed on the interlayer insulating layer,
wherein the second electrode is in contact with the metal insulating layer through the first opening.

6. The thin film transistor substrate of claim 4, the first thin film transistor further comprising:
the second electrode disposed on the metal insulating layer; and
an interlayer insulating layer disposed on the second electrode.

7. The thin film transistor substrate of claim 3, the first thin film transistor further comprising:
a gate insulating layer provided between the first active layer and the first gate electrode,
wherein one end and another end of the gate insulating layer correspond to one end and another side of the first gate electrode, and
wherein one side surface of the gate insulating layer is in contact with the metal insulating layer.

8. The thin film transistor substrate of claim 3,
wherein one end and another end of the metal insulating layer correspond respectively to one end and another end of the first gate electrode.

9. The thin film transistor substrate of claim 3,
wherein the metal insulating layer overlaps one end of the first active layer.

10. The thin film transistor substrate of claim 3,
wherein the first electrode comprises a plurality of first grooves, and
wherein the metal insulating layer is formed to be curved along the plurality of first grooves.

11. The thin film transistor substrate of claim 10,
wherein the second electrode is formed to be curved along the plurality of first grooves.

12. The thin film transistor substrate of claim 1,
wherein the metal insulating layer is provided between the first active layer and the first gate electrode, and
wherein the first gate electrode is extended to form the second electrode of the storage capacitor.

13. The thin film transistor substrate of claim 12, the first active layer comprising:
a first channel portion;
a first connection portion provided on one side of the first channel portion; and
a second connection portion provided on another side of the first channel portion,
wherein the metal insulating layer is in contact with an entire upper surface of the first channel portion.

14. The thin film transistor substrate of claim 10, the thin film transistor substrate further comprising a second thin film transistor disposed on the base substrate,
wherein the second thin film transistor comprises:
a second active layer disposed on the base substrate; and
a second gate electrode disposed on the second active layer,
wherein the second active layer comprises:
a second channel portion; and
a third connecting portion provided on one side of the second channel portion and having higher conductivity characteristics than the second channel portion,
wherein the third connecting portion is extended to form the first electrode of the storage capacitor.

15. The thin film transistor substrate of claim 14,
wherein the first active layer and the second active layer are disposed on a same layer.

16. The thin film transistor substrate of claim 14, the thin film transistor substrate further comprising:
a buffer layer provided between the base substrate and the second active layer and having a plurality of second grooves,
wherein the third connecting portion of the second active layer is provided in the plurality of second grooves.

17. The thin film transistor substrate of claim 16,
wherein an upper surface of the third connecting portion is formed to be curved along the plurality of second grooves.

18. The thin film transistor substrate of claim 17,
wherein the metal insulating layer is disposed on the third connecting portion, and
wherein the metal insulating layer is formed to be curved along the plurality of second grooves.

19. The thin film transistor substrate of claim 2,
wherein a carrier concentration of the metal insulating layer is lower than a carrier concentration of the first active layer.

20. The thin film transistor substrate of claim 2,
wherein an oxygen concentration of the metal insulating layer is greater than an oxygen concentration of the first active layer.

21. The thin film transistor substrate of claim 1,
wherein a thickness of the metal insulating layer is smaller than a thickness of the first active layer.

22. The thin film transistor substrate of claim 1,
wherein a thickness of the metal insulating layer ranges from 1.2 Å to 30 Å.

23. A display apparatus comprising the thin film transistor substrate of claim 1.
